(19) United States
(12) Patent Application Publication
(10) Pub. No.: US 2022/0252507 A1
(43) Pub. Date: Aug. 11, 2022

(54) SUBSTRATE PROCESSING APPARATUS, SUBSTRATE INSPECTING METHOD, AND STORAGE MEDIUM

(71) Applicant: Tokyo Electron Limited, Tokyo (JP)

(72) Inventor: Yasuaki NODA, Kumamoto (JP)

(21) Appl. No.: 17/617,979

(22) PCT Filed: Jun. 9, 2020
(86) PCT No.: PCT/JP2020/022612

§ 371 Date: Dec. 10, 2021

(30) Foreign Application Priority Data
Jun. 10, 2019 (JP) 2019-108148
May 28, 2020 (JP) 2020-093162

(51) Int. Cl. G01N 21/31; G01N 21/95; H04N 5/232; G06T 7/00

(52) U.S. Cl. CPC G01N 21/31; G01N 21/9501; G06T 2207/30148; G06T 7/0004; H04N 5/232

(57) ABSTRACT

A substrate processing apparatus includes: a holding unit configured to hold a substrate having a film formed on a surface; an imaging unit configured to acquire image data by imaging the surface of the substrate held by the holding unit; a spectroscopic measuring unit configured to acquire spectroscopic data by dispersing light from the surface of the substrate held by the holding unit; and a control unit configured to control the holding unit, the imaging unit, and the spectroscopic measuring unit.

### TECHNICAL FIELD

The present disclosure relates to a substrate processing apparatus, a method for inspecting a substrate, and a storage medium.

### BACKGROUND

Patent Document 1 discloses a configuration in which the thickness of a film formed on a substrate is calculated from an image obtained by imaging the surface of the substrate.

### PRIOR ART DOCUMENT

### Patent Document

Patent Document 1: Japanese Laid-Open Patent Publication No. 2015-215193

### SUMMARY OF THE INVENTION

### Problem to be Solved

The present disclosure provides a technique capable of accurately evaluating a film formed on a substrate.

### Means to Solve the Problem

A substrate processing apparatus according to an aspect of the present disclosure includes: a holding unit configured to hold a substrate having a film formed on a surface; an imaging unit configured to acquire image data by imaging the surface of the substrate held by the holding unit; a spectroscopic measuring unit configured to acquire spectroscopic data by dispersing light from the surface of the substrate held by the holding unit; and a controller configured to control the holding unit, the imaging unit, and the spectroscopic measuring unit.

### Effect of the Invention

According to the present disclosure, a technique capable of accurately evaluating a film formed on a substrate is provided.

### BRIEF DESCRIPTION OF THE DRAWINGS

FIG. 1 is a schematic view illustrating an example of a schematic configuration of a substrate processing system.

FIG. 2 is a schematic view illustrating an example of a coating/developing apparatus.

FIG. 3 is a schematic view illustrating an example of an inspector.

FIG. 4 is a block diagram illustrating an example of a functional configuration of a control device.

FIG. 5 is a block diagram illustrating an example of a hardware configuration of the control device.

FIG. 6 is a flowchart illustrating an example of control (inspection of a wafer) by the control device.

FIG. 7 is a view illustrating an example of an acquisition position of spectroscopic spectrum data.

FIG. 8 is a flowchart illustrating an example of control (estimating a film thickness from change in color) by the control device.

FIG. 9 is a flowchart illustrating an example of control (estimating a film thickness from spectroscopic spectrum data) by the control device.

FIG. 10 is a flowchart illustrating an example of determination on pass or not.

FIG. 11 is a flowchart illustrating an example of control (detailed inspection) by the control device.

FIG. 12 is a flowchart illustrating an example of control (processing of a pattern wafer when creating a model) by the control device.

FIG. 13 is a flowchart illustrating an example of control (processing of a bear wafer when creating a model) by the control device.

FIG. 14 is a flowchart illustrating an example of control (processing of a wafer when creating a model) by the control device.

FIG. 15 is a flowchart illustrating an example of control (creating a model) by the control device.

FIG. 16 is a schematic view illustrating an example of another inspector according to Application Example 1.

FIG. 17 is a perspective view illustrating an example of a periphery exposing unit of the inspector.

FIG. 18 is a schematic view illustrating an example of another inspector according to Application Example 2.

FIG. 19 is a schematic view illustrating an example of another inspector according to Application Example 3.

### DETAILED DESCRIPTION TO EXECUTE THE INVENTION

Hereinafter, various embodiments will be described.

In an embodiment, a substrate processing apparatus includes: a holding unit configured to hold a substrate having a film formed on a surface; an imaging unit configured to acquire image data by imaging the surface of the substrate held by the holding unit; a spectroscopic measuring unit configured to acquire spectroscopic data by dispersing light from the surface of the substrate held by the holding unit; and a control unit configured to control the holding unit, the imaging unit, and the spectroscopic measuring unit.

In an embodiment, a substrate processing apparatus includes: a holding unit configured to hold a substrate having a film formed on a surface; an imaging unit configured to acquire image data by imaging the surface of the substrate held by the holding unit; and a spectroscopic measuring unit configured to acquire spectroscopic data by dispersing light from the surface of the substrate held by the holding unit.

As described above, with a configuration in which, in a state of being held by the holding unit, the image data obtained by imaging the surface of the substrate may be acquired, and the spectroscopic data related to light from the surface may be acquired, it is possible to accurately evaluate the film formed on the substrate. That is, since it is possible to evaluate the film formed on the substrate using both the image data and the spectroscopic data, it is possible to evaluate the film from a plurality of types of data, and the accuracy of the evaluation may be enhanced.

Here, the imaging unit may acquire an image related to the entire surface of the substrate, and the spectroscopic measuring unit may acquire spectroscopic data by dispersing light from a plurality of different regions included in the surface of the substrate, respectively.

With the above configuration, it is possible to acquire information related to the entire surface of the substrate from the image data acquired by the imaging unit, and thus, the overall evaluation on the surface of the substrate may be performed. Meanwhile, since the spectroscopic measuring unit may acquire the spectroscopic data related to a plurality of different regions included in the surface of the substrate, it is possible to acquire information related to spectroscopic characteristics at a plurality of positions in the substrate, and thus, the evaluation using, for example, variations in the spectroscopic characteristics may be performed. Therefore, it is possible to evaluate the film of the surface of the substrate in a more multifaceted manner.

The controller may control the holding unit, the imaging unit, and the spectroscopic measuring unit. Further, the controller may cause the imaging unit to image the surface of the substrate while moving the holding unit in one direction, and in parallel, cause the spectroscopic measuring unit to acquire spectroscopic data by dispersing light from a plurality of different regions included in the surface of the substrate.

With the above configuration, it is possible to simultaneously acquire the image data by the imaging unit and to acquire the spectroscopic data by the spectroscopic measuring unit while moving the holding unit in one direction. Therefore, even though both the image data and the spectroscopic data are acquired, it is possible to prevent the required time from becoming long, and the image data and the spectroscopic data may efficiently be acquired.

The controller may evaluate a film formation status of the surface of the substrate based on the image data imaged by the imaging unit.

As described above, with the configuration in which the film formation status of the surface of the substrate is evaluated based on the image data, for example, the handling of the spectroscopic data may be changed based on the evaluation result of the film formation status based on the image data. As a result, the image data and the spectroscopic data may be handled more appropriately in the inspection of the substrate.

A periphery exposing unit configured to expose a peripheral edge region of the substrate held by the holding unit may be further provided, and the controller may control the periphery exposing unit.

As described above, even when the periphery exposing unit that exposes the peripheral edge region is further provided, it is possible to acquire the image data obtained by imaging the surface of the substrate in a state of being held by holding unit. Further, with the configuration capable of acquiring spectroscopic data related to light from the surface, it is possible to accurately evaluate the film formed on the substrate. Moreover, with the above configuration, it is possible to evaluate the exposure result of the peripheral edge region of the substrate by the periphery exposing unit.

The controller may cause the spectroscopic measuring unit to acquire spectroscopic data by dispersing light from a plurality of locations on each of the substrate before and after exposure by the periphery exposing unit.

As described above, by acquiring the spectroscopic data based on the light from a plurality of locations on each of the substrate before and after exposure by the periphery exposing unit, it is possible to grasp the difference in the spectroscopic data before and after exposure. Therefore, it is possible to evaluate the exposure result by the periphery exposing unit based on the spectroscopic data before and after the exposure.

In an embodiment, a method for inspecting a substrate is a method for inspecting a substrate after film formation, and includes: acquiring image data by imaging a surface of the substrate held by a holding unit; acquiring spectroscopic data by dispersing light from some regions included in the surface of the substrate held by the holding unit by a spectroscopic measuring unit; determining whether the film meets acceptance criteria based on the image data and the spectroscopic data; when the film does not meet the acceptance criteria in the determining, performing a same film formation processing on an inspection substrate as for the substrate; and acquiring spectroscopic data by dispersing light from measurement positions two-dimensionally dispersed on the surface of the inspection substrate after film formation held by the holding unit by the spectroscopic measuring unit, respectively.

As described above, as a result of determining whether the film formed on the substrate meets the acceptance criteria based on the image data and the spectroscopic data, when the acceptance criteria are not met, a film formation processing is performed on the inspection substrate. Then, with respect to the inspection substrate after the film formation, spectroscopic data from the measurement positions two-dimensionally dispersed using the spectroscopic measuring unit is acquired and a detailed measurement is performed. With this configuration, when a film formed on a normal substrate does not meet the acceptance criteria, a detailed measurement related to the inspection substrate after the film formation may be performed using the same spectroscopic measuring unit. Further, with respect to the normal substrate, not only the film may appropriately be evaluated based on image data and spectroscopic data, but also the detailed inspection for the case where the film does not meet acceptance criteria may be performed using the same spectroscopic measuring unit, and thus, the film may be evaluated in more detail.

In the acquiring image data, the imaging unit images the surface of the substrate while moving the holding unit in one direction, and in parallel, as the acquiring spectroscopic data, the spectroscopic measuring unit acquires spectroscopic data by dispersing light from a plurality of different regions included in the surface of the substrate.

With the above configuration, it is possible to simultaneously acquire the image data by the imaging unit and to acquire the spectroscopic data by the spectroscopic measuring unit while moving the holding unit in one direction. Therefore, even though both the image data and the spectroscopic data are acquired, it is possible to prevent the required time from becoming long, and the image data and the spectroscopic data may efficiently be acquired.

In another embodiment, a storage medium is a non-transitory computer-readable storage medium having stored therein a program that causes an apparatus to execute the method for inspecting a substrate described above.

Hereinafter, various embodiments will be described. In the descriptions, the same elements or elements having the same function are denoted by the same reference numerals, and redundant descriptions thereof will be omitted.

[Substrate Processing System]

A substrate processing system 1 is a system that performs formation, exposure, and development of a photosensitive film on a substrate. The processing target substrate is, for example, a semiconductor wafer W.

The substrate processing system 1 includes a coating/developing apparatus 2 and an exposing apparatus 3. The exposing apparatus 3 performs an exposing processing of a resist film (photosensitive film) formed on the wafer W (substrate). Specifically, the exposing apparatus 3 irradiates an energy beam to an exposure target portion of the resist film according to a method such as liquid immersion exposure. The coating/developing apparatus 2 performs a processing of forming a resist film on the surface of the wafer W (substrate) before the exposing processing by the exposing apparatus 3, and a developing processing of the resist film after the exposing processing.

[Substrate Processing Apparatus]

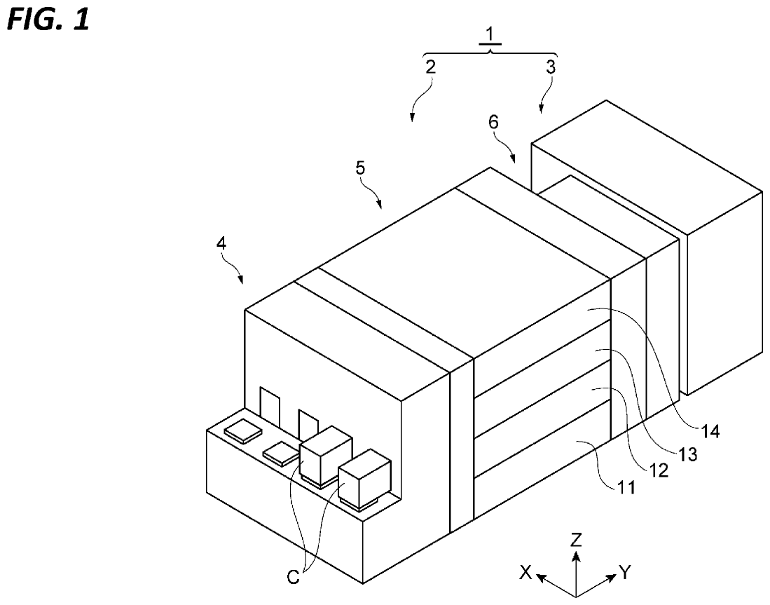

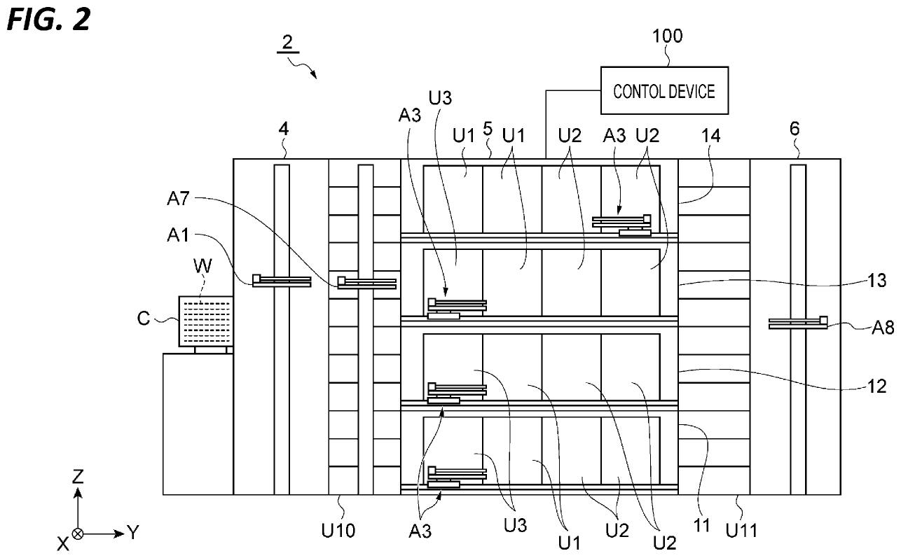

Hereinafter, a configuration of the coating/developing apparatus 2 as an example of the substrate processing apparatus will be described. As illustrated in FIGS. 1 and 2, the coating/developing apparatus 2 includes a carrier block 4, a processing block 5, an interface block 6, and a control device 100 (controller). The coating/developing apparatus 2 as the substrate processing apparatus described in the embodiment corresponds to a substrate inspecting system that inspects a film formation status on a substrate. The function as the substrate inspecting system will be described later.

The carrier block 4 performs introducing the wafer W into the coating/developing apparatus 2 and taking the wafer W out from the inside of the coating/developing apparatus 2. For example, the carrier block 4 may support a plurality of carriers C (receiver) for the wafer W, and incorporates a transfer device A1 including a delivery arm. The carrier C accommodates, for example, a plurality of circular wafers W. The transfer device A1 takes out the wafer W from the carrier C to pass the wafer W to the processing block 5, and receives the wafer W from the processing block 5 and returns the wafer W to the inside of the carrier C. The processing block 5 includes a plurality of processing modules 11, 12, 13, and 14.

The processing module 11 incorporates a plurality of coating units U1, a plurality of heat treatment units U2, a plurality of inspecting units U3, and a transfer device A3 that transfers the wafer W to these units. The processing module 11 forms a lower layer film on the surface of a wafer W by the coating units U1 and the heat treatment units U2. A coating unit U1 in the processing module 11 coats a processing liquid for forming the lower layer film on the wafer W, for example, while rotating the wafer W at a predetermined rotation speed. A heat treatment unit U2 in the processing module 11 performs various heat treatments accompanying the formation of the lower layer film. The heat treatment unit U2 incorporates, for example, a heating plate and a cooling plate, and performs a heat treatment by heating the wafer W to a predetermined heating temperature with the heating plate and cooling the heated wafer W with the cooling plate. An inspecting unit U3 performs a processing to inspect the surface state of the wafer W, and acquires, for example, information related to a surface image or a film thickness as information indicating the surface state of the wafer W.

The processing module 12 incorporates a plurality of coating units U1, a plurality of heat treatment units U2, a plurality of inspecting units U3, and a transfer device A3 that transfers the wafer W to these units. The processing module 12 forms an intermediate film on the lower layer film by the coating units U1 and the heat treatment units U2. A coating unit U1 in the processing module 12 forms a coating film on the surface of the wafer W by coating a processing liquid for forming the intermediate film. A heat treatment unit U2 in the processing module 12 performs various heat treatments accompanying the formation of the intermediate film. The heat treatment unit U2 incorporates, for example, a heating plate and a cooling plate, and performs a heat treatment by heating the wafer W to a predetermined heating temperature with the heating plate and cooling the heated wafer W with the cooling plate. An inspecting unit U3 performs a processing to inspect the surface state of the wafer W, and acquires, for example, information related to a surface image or a film thickness as information indicating the surface state of the wafer W.

The processing module 13 incorporates a plurality of coating units U1, a plurality of heat treatment units U2, a plurality of inspecting units U3, and a transfer device A3 that transfers the wafer W to these units. The processing module 13 forms a resist film on the intermediate film by the coating units U1 and the heat treatment units U2. A coating unit U1 in the processing module 13 coats a processing liquid for forming the resist film on the intermediate film, for example, while rotating the wafer W at a predetermined rotation speed. A heat treatment unit U2 in the processing module 13 performs various heat treatments accompanying the formation of the resist film. The heat treatment unit U2 in the processing module 13 forms the resist film by performing a heat treatment (pre applied bake: PAB) at a predetermined heating temperature on the wafer W on which the coating film is formed. An inspecting unit U3 performs a processing to inspect the surface state of the wafer W, and acquires, for example, information related to a film thickness as information indicating the surface state of the wafer W.

The processing module 14 incorporates a plurality of coating units U1, a plurality of heat treatment units U2, and a transfer device A3 that transfers the wafer W to these units. The processing module 14 performs a developing processing of the resist film after exposure, by the coating units U1 and the heat treatment units U2. A coating unit U1 in the processing module 14 performs the developing processing of the resist film by coating a developing solution on the surface of the wafer W after the exposure has finished, and then, cleansing the wafer W with a rinsing liquid, for example, while rotating the wafer W at a predetermined rotation speed. A heat treatment unit U2 in the processing module 14 performs various heat treatments accompanying the developing processing. Specific examples of the heat treatments may include, for example, a heat treatment before the developing processing (post exposure bake: PEB), a heat treatment after the developing processing (post bake: PB).

A shelf unit U10 is provided at the carrier block 4 side within the processing block 5. The shelf unit U10 is partitioned into a plurality of vertically arranged cells. A transfer device A7 including an elevating arm is provided in the vicinity of the shelf unit U10. The transfer device A7 moves the wafer W up and down between the cells of the shelf unit U10.

A shelf unit U11 is provided at the interface block 6 side within the processing block 5. The shelf unit U11 is partitioned into a plurality of vertically arranged cells.

The interface block 6 performs a delivery of the wafer W to and from the exposing apparatus 3. For example, the interface block 6 incorporates a transfer device A8 including a delivery arm, and is connected to the exposing apparatus 3. The transfer device A8 passes the wafer W disposed on the shelf unit U11 to the exposing apparatus 3, and receives the wafer W from the exposing apparatus 3 and returns the wafer W to the shelf unit U11.

[Inspecting Unit]

The inspecting unit U3 included in the processing modules 11 to 13 will be described. The inspecting unit U3 acquires information related to the surface of the film (lower layer film, intermediate film, or resist film) formed by the coating unit U1 and the heat treatment unit U2, and information related to the film thickness.

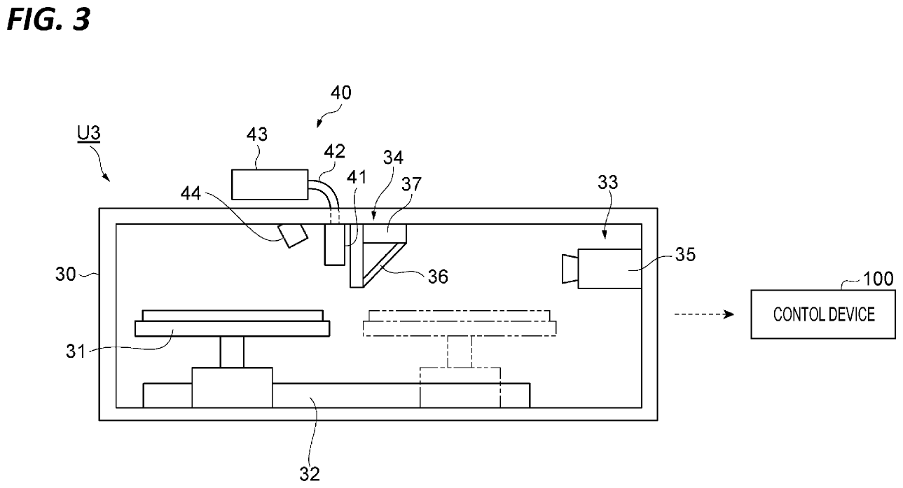

As illustrated in FIG. 3, the inspecting unit U3 includes a housing 30, a holding unit 31, a linear driver 32, an imaging unit 33, a light projecting/reflecting unit 34, and a spectroscopic measuring unit 40. The holding unit 31 holds the wafer W horizontally. The linear driver 32 moves the holding unit 31 along a horizontal linear path, for example, using an electric motor as a power source. The imaging unit 33 includes a camera 35, for example, a CCD camera. The camera 35 is provided on one end side in the inspecting unit U3 in the moving direction of the holding unit 31, and faces the other end side in the moving direction. The light projecting/reflecting unit 34 projects light to an imaging range, and guides the reflected light from the imaging range to the camera 35 side. For example, the light projecting/reflecting unit 34 includes a half mirror 36 and a light source 37. The half mirror 36 is provided in an intermediate portion of the moving range of the linear driver 32 at a position higher than the holding unit 31, and reflects light from below to the camera 35 side. The light source 37 is provided on the half mirror 36, and irradiates illumination light downward through the half mirror 36.

The spectroscopic measuring unit 40 has a function of causing light from the wafer W to be incident, dispersing the light, and acquiring a spectroscopic spectrum. The spectroscopic measuring unit 40 includes an incident unit 41 that causes light from the wafer W to be incident, a waveguide 42 that transmits the light incident on the incident unit 41, a spectroscope 43 that acquires a spectroscopic spectrum by dispersing the light transmitted by the waveguide 42, and a light source 44. The incident unit 41 is configured to be capable of causing light from the center of the wafer W when the wafer W held by the holding unit 31 moves along with the driving by the linear driver 32. That is, it is provided at a position corresponding to the movement path of the center of the holding unit 31 moved by driving the linear driver 32. Then, the incident unit 41 is attached such that, when the wafer W is moved by the movement of the holding unit 31, the incident unit 41 is relatively moved with respect to the surface of the wafer W along the radial direction of the wafer W. Therefore, the spectroscopic measuring unit 40 may acquire a spectroscopic spectrum at each position along the radial direction of the wafer W including the center of the wafer W. The waveguide 42 is made of, for example, an optical fiber. The spectroscope 43 disperses the incident light and acquires a spectroscopic spectrum including intensity information corresponding to each wavelength. The light source 44 irradiates illumination light downward. Therefore, the reflected light from the wafer W is incident on the spectroscope 43 passing through the incident unit 41 and the waveguide 42.

The wavelength range of the spectroscopic spectrum acquired by the spectroscope 43 may be, for example, a wavelength range of visible light (380 nm to 780 nm). Therefore, a light source that emits visible light is used as the light source 44 and the reflected light at the surface of the wafer W with respect to the light from the light source 44 is dispersed by the spectroscope 43, and thus, spectroscopic spectrum data (spectroscopic data) in the wavelength range of visible light may be obtained. The wavelength range of the spectroscopic spectrum acquired by the spectroscope 43 is not limited to the range of visible light, but may be, for example, a wavelength range including infrared rays or ultraviolet rays. The spectroscope 43 and the light source 44 may be appropriately selected according to the wavelength range of the acquired spectroscopic spectrum data.

The inspecting unit U3 acquires the image data of the surface of the wafer W by being operated as follows. First, the linear driver 32 moves the holding unit 31. Therefore, the wafer W passes under the half mirror 36. In the passing process, reflected light from each part of the surface of the wafer W is sequentially sent to the camera 35. The camera 35 forms an image of the reflected light from each part of the surface of the wafer W and acquires image data of the surface of the wafer W. When the film thickness of the film formed on the surface of the wafer W is changed, the image data of the surface of the wafer W imaged by the camera 35 is changed, for example, the color of the surface of the wafer W is changed according to the film thickness. That is, acquiring the image data of the surface of the wafer W corresponds to acquiring the information related to the film thickness of the film formed on the surface of the wafer W. This point will be described later.

The image data acquired by the camera 35 is sent to the control device 100. In the control device 100, the film thickness of the film of the surface of the wafer W may be estimated based on the image data, and the estimation result is held as an inspection result in the control device 100.

Further, at the same time as the image data is acquired by the inspecting unit U3, the spectroscopic measuring unit 40 causes the light from the surface of the wafer W to be incident to perform spectroscopic measurement. When the linear driver 32 moves the holding unit 31, the wafer W passes under the incident unit 41. In the passing process, the reflected light from each part of the surface of the wafer W is incident on the incident unit 41, passes through the waveguide 42, and is incident on the spectroscope 43. In the spectroscope 43, the incident light is dispersed and spectroscopic spectrum data is acquired. When the film thickness of the film formed on the surface of the wafer W is changed, for example, the spectroscopic spectrum is changed according to the film thickness. That is, acquiring the spectroscopic spectrum data of the surface of the wafer W corresponds to acquiring the information related to the film thickness of the film formed on the surface of the wafer W. This point will be described later. In the inspecting unit U3, the image data acquisition and the spectroscopic measurement may be performed in parallel. As a result, it is possible to perform the measurement in a short time as compared with the case where these are performed individually.

The spectroscopic spectrum data acquired by the spectroscope 43 is sent to the control device 100. In the control device 100, the film thickness of the film of the surface of the wafer W may be estimated based on the spectroscopic spectrum data, and the estimation result is held as an inspection result in the control device 100.

[Control Device]

An example of the control device 100 will be described in detail. The control device 100 controls each element included in the coating/developing apparatus 2. The control device 100 is configured to perform a process processing including forming each film described above on the surface of the wafer W, and performing the developing processing. Further, the control device 100 is configured to perform, for example, correcting of parameters related to the process processing based on the result of the process processing. Details of the process processing will be described later.

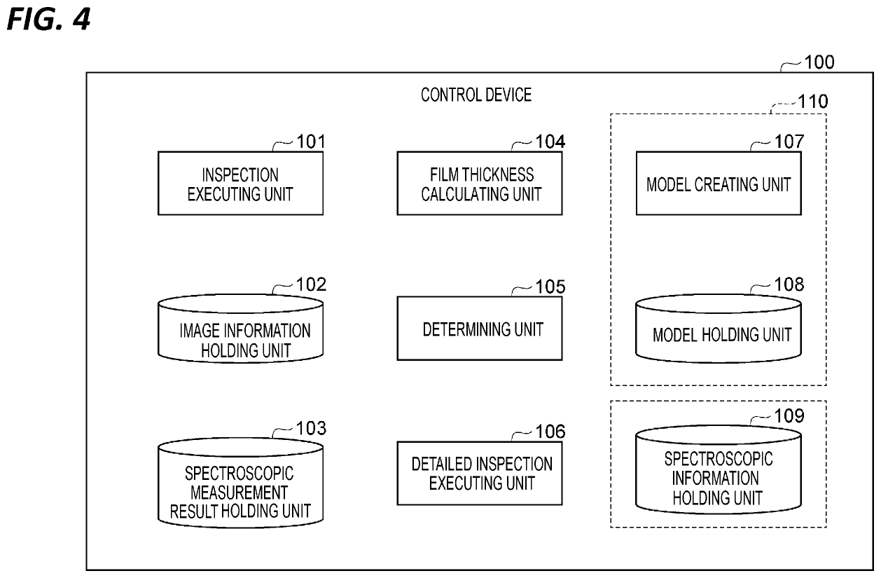

As illustrated in FIG. 4, the control device 100 includes an inspection executing unit 101, an image information holding unit 102, a spectroscopic measurement result holding unit 103, a film thickness calculating unit 104, and a determining unit 105 as functional configurations. Further, the control device 100 includes a detailed inspection executing unit 106, a model creating unit 107, a model holding unit 108, and a spectroscopic information holding unit 109.

The inspection executing unit 101 has a function of controlling an operation related to the inspection of the wafer W in the inspecting unit U3. As a result of the inspection in the inspecting unit U3, image data and spectroscopic spectrum data are acquired.

The image information holding unit 102 has a function of acquiring and holding the image data obtained by imaging the surface of the wafer W by the imaging unit 33 in the inspecting unit U3. The image data held in the image information holding unit 102 is used for estimation of the film thickness of the film formed on the wafer W. According to the film thickness of the film formed on the wafer W, the image data may be used for evaluation of the film formation state, not for evaluation of the film thickness of the film. This point will also be described later.

The spectroscopic measurement result holding unit 103 has a function of acquiring and holding the spectroscopic spectrum data related to the surface of the wafer W by the spectroscope 43 in the inspecting unit U3. The spectroscopic spectrum data held in the spectroscopic measurement result holding unit 103 is used for estimation of the film thickness of the film formed on the wafer W.

The film thickness calculating unit 104 has a function of calculating the film thickness of the film formed on the wafer W based on the image data held in the image information holding unit 102 and the spectroscopic spectrum data held in the spectroscopic measurement result holding unit 103. Details of the procedure for calculating the film thickness will be described later.

The determining unit 105 has a function of determining whether the film thickness calculated by the film thickness calculating unit 104 is appropriate. Since the formation of the film is performed by the coating unit U1 and the heat treatment unit U2 in the previous step in the inspecting unit U3, the determination corresponds to the determination whether the coating unit U1 and the heat treatment unit U2 are operating properly.

The detailed inspection executing unit 106 has a function of executing a detailed inspection for confirming the operation of the coating unit U1 and the heat treatment unit U2 when it is determined that there is a problem with the film thickness as a result of the determination by the determining unit 105. Although the detailed inspection will be described later, a bare wafer on which a pattern is not formed is prepared as an inspection wafer, a film is formed on the wafer, and the film thickness is evaluated.

The model creating unit 107 and the model holding unit 108 has a function of creating and holding a model used when calculating the film thickness from the image data. Color information on the surface of the wafer W may be acquired from the image data imaged by the imaging unit U3. Therefore, in the model creating unit 107, a model capable of estimating the film thickness based on the color information on the surface of the wafer W is created, and the created model is held in the model holding unit 108. In the film thickness calculating unit 104, the film thickness is estimated with respect to the inspection target wafer W using the model.

The spectroscopic information holding unit 109 has a function of holding spectroscopic information used when calculating the film thickness from the spectroscopic spectrum data. The spectroscopic spectrum data acquired in the inspecting unit U3 is changed according to the type and the film thickness of the film formed on the surface of the wafer W. Therefore, in the spectroscopic information holding unit 109, the information related to the correspondence relationship between the film thickness and the spectroscopic spectrum is held. In the film thickness calculating unit 104, the film thickness is estimated with respect to the inspection target wafer W (target substrate) based on the information held in the spectroscopic information holding unit 109.

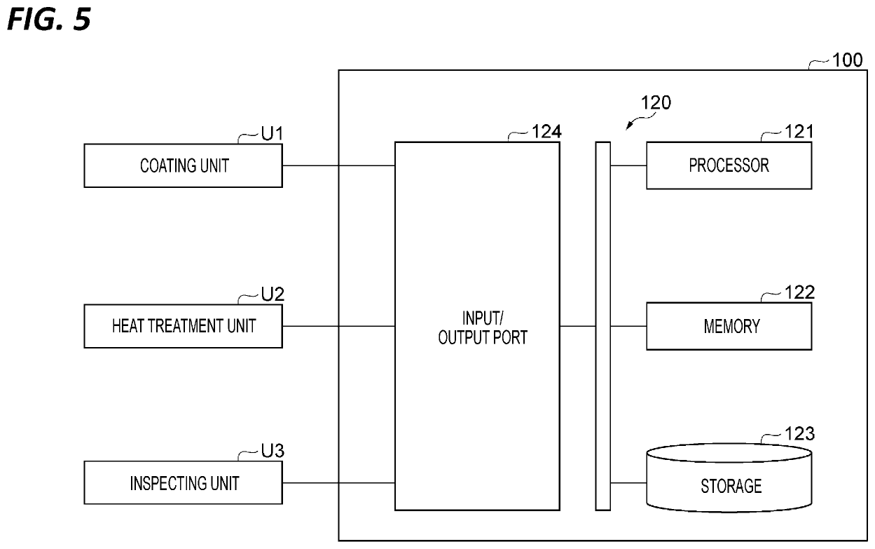

The control device 100 is constituted by one or a plurality of control computers. For example, the control device 100 includes a circuit 120 illustrated in FIG. 5. The circuit 120 includes one or a plurality of processors 121, a memory 122, a storage 123, and an input/output port 124. The storage 123 includes a computer-readable storage medium, for example, a hard disk. The storage medium stores a program that causes the control device 100 to execute the process processing procedure (to be described later). The storage medium may be a withdrawable medium such as a non-volatile semiconductor memory, a magnetic disk, and an optical disk. The memory 122 temporarily stores a program loaded from the storage medium of the storage 123 and a calculation result by the processor 121. The processor 121 executes the program in cooperation with the memory 122 so as to implements each functional module described above. The input/output port 124 performs input/output of an electric signal to/from a control target member according to a command from the processor 121.

The hardware configuration of the control device 100 is not necessarily limited to those constituting each functional module by a program. For example, each functional module of the control device 100 may be implemented by dedicated logic circuits or an application specific integrated circuit (ASIC) in which the logic circuits are integrated.

In FIG. 4 and in the following embodiments, a case where the above constituents are included in the control device 100 will be described, but the control device 100 may not include all the above functions. For example, only a model managing unit 110 including the model creating unit 107 and the model holding unit 108, or the model creating unit 107 may be provided in an external device. In other words, the functions may be provided in, for example, a device different from the control device 100 that controls the coating/developing apparatus 2. In this manner, when the function related to the creation of the model is provided in the control device 100 and the external device, the external device and the control device 100 cooperate with each other to exert the function described in the following embodiment. Further, in this case, the external device to which the function corresponding to the control device 100 described in the present embodiment is mounted and the substrate processing apparatus described in the present embodiment may integrally function as the substrate inspecting system.

[Process Processing Procedure]

Subsequently, a process processing procedure executed in the coating/developing apparatus 2 will be described as an example of the coating/developing processing.

In the process processing procedure, first, the control device 100 controls the transfer device A1 to transfer the process processing target wafer W within the carrier C to the shelf unit U10, and controls the transfer device A7 to dispose the wafer W in the cell for the processing module 11.

Subsequently, the control device 100 controls the transfer device A3 to transfer the wafer W in the shelf unit U10 to the coating unit U1 and the heat treatment unit U2 within the processing module 11. Further, the control device 100 controls the coating unit U1 and the heat treatment unit U2 to form the lower layer film on the surface of the wafer W. After forming the lower layer film, the control device 100 controls the transfer device A3 to transfer the wafer W to the inspecting unit U3, and the surface state of the wafer W may be inspected using the inspecting unit U3. Thereafter, the control device 100 controls the transfer device A3 to return the wafer W on which the lower layer film is formed to the shelf unit U10, and controls the transfer device A7 to dispose the wafer W in the cell for the processing module 12.

Subsequently, the control device 100 controls the transfer device A3 to transfer the wafer W in the shelf unit U10 to the coating unit U1 and the heat treatment unit U2 within the processing module 12. Further, the control device 100 controls the coating unit U1 and the heat treatment unit U2 to form the intermediate film on the lower layer film of the wafer W. For example, the control device 100 controls the coating unit U1 so as to form the intermediate film by coating a processing liquid for forming the intermediate film on the lower layer film of the wafer W. Subsequently, the control device 100 controls the heat treatment unit U2 to execute a heat treatment on the intermediate film. After forming the intermediate film, the control device 100 controls the transfer device A3 to transfer the wafer W to the inspecting unit U3, and controls to inspect the surface state of the wafer W using the inspecting unit U3. Thereafter, the control device 100 controls the transfer device A3 to return the wafer W to the shelf unit U10, and controls the transfer device A7 to dispose the wafer W in the cell for the processing module 13.

Subsequently, the control device 100 controls the transfer device A3 to transfer the wafer W in the shelf unit U10 to each unit within the processing module 13, and controls the coating unit U1 and the heat treatment unit U2 to form the resist film on the intermediate film of the wafer W. For example, the control device 100 controls the coating unit U1 so as to form the resist film by coating a processing liquid for forming the resist film on the intermediate film of the wafer W. Subsequently, the control device 100 controls the heat treatment unit U2 to execute a heat treatment on the resist film. After forming the resist film, the control device 100 controls the transfer device A3 to transfer the wafer W to the inspecting unit U3, and the surface state (e.g., film thickness of the upper layer film) of the wafer W may be inspected using the inspecting unit U3. Thereafter, the control device 100 controls the transfer device A3 to transfer the wafer W to the shelf unit U11.

Subsequently, the control device 100 controls the transfer device A8 to transfer the wafer W in the shelf unit U11 to the exposing apparatus 3. Thereafter, the control device 100 controls the transfer device A8 to accept the wafer W on which an exposing processing is performed from the exposing apparatus 3 to dispose the wafer W in the cell for the processing module 14 in the shelf unit Ulf.

Subsequently, the control device 100 controls the transfer device A3 to transfer the wafer W in the shelf unit Ulf to each unit within the processing module 14, and controls the coating unit U1 and the heat treatment unit U2 to perform the developing processing on the resist film of the wafer W. Thereafter, the control device 100 controls the transfer device A3 to return the wafer W to the shelf unit U10, and controls the transfer device A7 and the transfer device A1 to return the wafer W into the carrier C. Accordingly, the process processing is completed.

[Method for Inspecting Substrate]

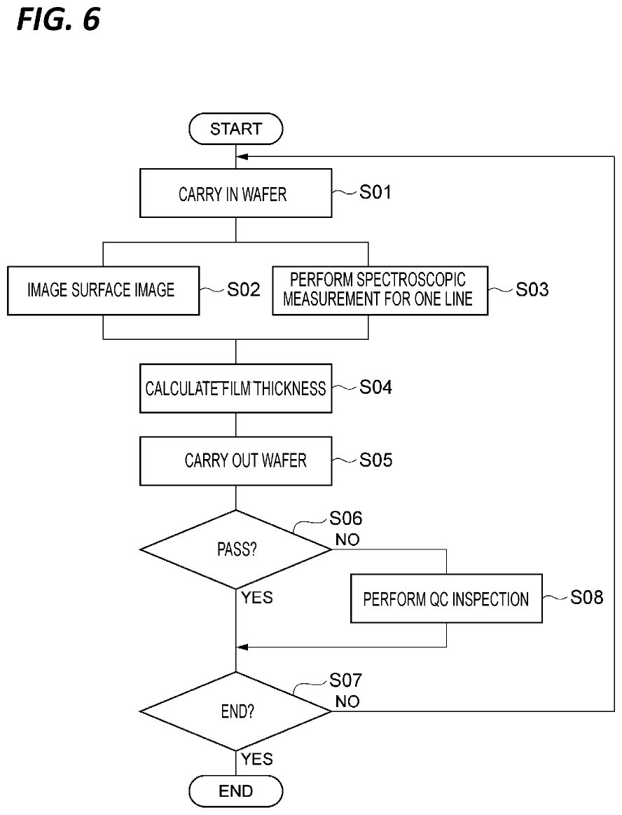

Subsequently, the method for inspecting a substrate in the processing modules 11 to 13 by the control device 100 will be described with reference to FIGS. 6 to 11. The method for inspecting a substrate is a method related to inspection of the wafer W after the film formation performed in the inspecting unit U3 provided in the processing modules 11 to 13. The inspecting unit U3 inspects whether a desired film formation is performed on the wafer W after the film formation. Specifically, the surface state and the film thickness of the film formed on the wafer W are evaluated. Since, for example, the imaging unit 33 and the spectroscopic measuring unit 40 are provided as described above, the inspecting unit U3 may acquire image data obtained by imaging the surface of the wafer W by the imaging unit 33, and spectroscopic spectrum data of the surface of the wafer W by the spectroscopic measuring unit 40. The control device 100 evaluates the film formation status based on these data. In purpose of evaluating the film formation states of the wafer W, the inspection may be performed by the inspecting unit U3 after forming each of the lower layer film, the intermediate film, and the resist film in the processing modules 11 to 13.

FIG. 6 is a flowchart illustrating a series of flows of the method for inspecting a substrate in the inspecting unit U3. First, the control device 100 executes step S01. In step S01, the wafer Won which the film is formed in the coating unit U1 and the heat treatment unit U2 is carried into the inspecting unit U3. The wafer W is held by the holding unit 31.

Subsequently, the inspection executing unit 101 of the control device 100 executes step S02 (image acquiring step). In step S02, the surface of the wafer W is imaged by the imaging unit 33. Specifically, the surface of the wafer W is imaged by the imaging unit 33 while moving the holding unit 31 in a predetermined direction by driving the linear driver 32. Therefore, in the imaging unit 33, image data related to the surface of the wafer W is acquired. The image data is held in the image information holding unit 102 of the control device 100.

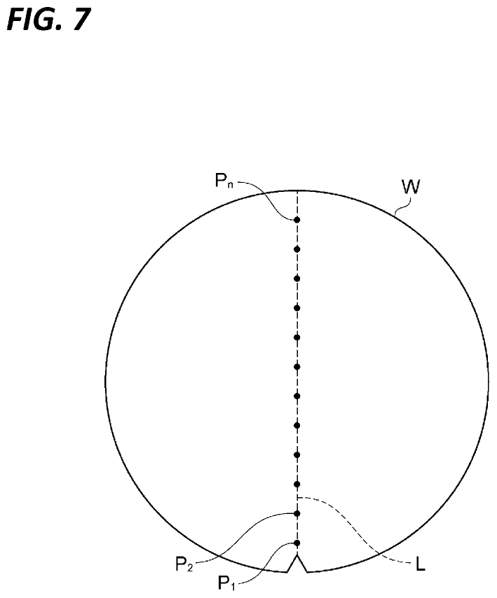

The inspection executing unit 101 of the control device 100 executes step S03 (spectroscopic measuring step) at the same time as the execution of step S02. In step S03, spectroscopic measurement for one line of the surface of the wafer W is performed by the spectroscopic measuring unit 40. As described above, since the incident unit 41 of the spectroscopic measuring unit 40 is provided on the path through which the center of the wafer W held by the holding unit 31 passes when the holding unit 31 moves, it is possible to acquire the spectroscopic spectrum at each position along the radial direction of the wafer W including the center of the wafer W. Therefore, as illustrated in FIG. 7, the reflected light on the surface along a center line L passing through the center of the wafer W is incident on the incident unit 41. In the spectroscope 43, measurement related to the spectroscopic spectrum of light incident at a predetermined interval is performed. As a result, in the spectroscope 43, spectroscopic spectrum data corresponding to, for example, n positions of P₁ to Pₙ illustrated in FIG. 7, as a plurality of locations along the center line L. In this manner, the spectroscopic spectrum data related to the surface of the wafer W at a plurality of locations along the center line L of the wafer W is acquired using the spectroscope 43. Here, n may be appropriately changed by the interval of the spectroscopic measurement by the spectroscope 43 and the movement speed of the wafer W by the holding unit 31. The spectroscopic spectrum data acquired by the spectroscope 43 is held in the spectroscopic measurement result holding unit 103 of the control device 100.

The film thickness calculating unit 104 of the control device 100 executes step S04. In step S04, the film thickness of the film of the surface of the wafer W is calculated based on the image data related to the surface of the wafer W or the spectroscopic spectrum data by the spectroscopic measurement.

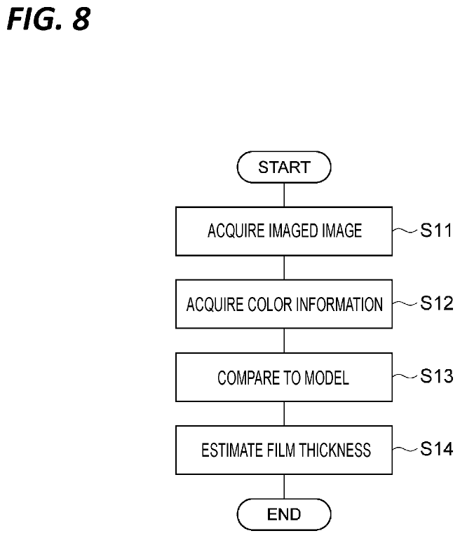

A procedure when calculating the film thickness using the image data will be described with reference to FIG. 8. In the calculation of the film thickness using the image data, the film thickness model created by the model creating unit 107 and held in the model holding unit 108 is used. The film thickness model is a model for calculating the film thickness from information (change in color between before and after forming a predetermined film) related to a change in color of each pixel in the image data obtained by imaging the surface of the wafer W when forming a predetermined film, and a model illustrating correspondence relationship between the information related to the change in color and the film thickness. The information related to the change in color at each position of the image data is acquired by creating such a model in advance in the model creating unit 107 of the control device 100 and holding in the model holding unit 108, and the film thickness may be estimated from the change in color. Although the method for creating the film thickness model will be described later, the surfaces of both the wafer W on which each processing up to the previous step is performed and the wafer W on which a predetermined film is formed thereafter are imaged to acquire image data, and how the color has changed is specified. Further, the film thickness of the wafer on which a film is formed under the same conditions is measured. Therefore, it is possible to specify the correspondence relationship between the film thickness and the change in color. By repeating the measurement while changing the film thickness, it is possible to obtain the correspondence relationship between the information related to the change in color and the film thickness.

Specifically, the method for calculating the film thickness from the image data is as illustrated in FIG. 8. First, after acquiring the imaged image data (step S11), the information related to the change in color for each pixel is acquired from the image data (step S12). In order to acquire the information related to the change in color, a processing that calculates the difference from the image data before the film formation may be performed. Thereafter, a comparison with the film thickness model held in the model holding unit 108 is performed (step S13). As a result, it is possible to estimate the film thickness of the region imaged by the pixel for each pixel (step S14). Therefore, it is possible to estimate the film thickness for each pixel, that is, at each position of the surface of the wafer W.

It is possible to calculate (estimate) the film thickness based on the image data described above when the film formed on the wafer W is relatively thin (e.g., approximately 500 nm or less), but it is difficult to calculate when the film thickness increases. This is because, as the film thickness increases, the change in color with respect to the change in film thickness decreases, and thus it is difficult to accurately estimate the film thickness from the information related to the change in color. Therefore, when a film having a large film thickness is formed, the estimation of the film thickness is performed based on the spectroscopic spectrum data.

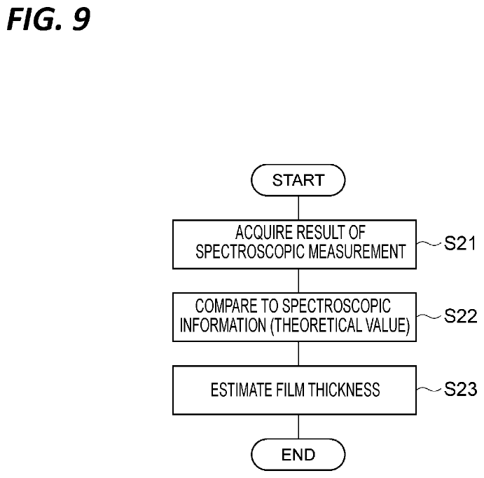

A procedure when calculating the film thickness using the spectroscopic spectrum data will be described with reference to FIG. 9. The calculation of the film thickness using the spectroscopic spectrum data uses a change in reflectance according to the film thickness of the film of the surface. When a wafer with a film formed on the surface is irradiated with light, the light is reflected at the surface of the uppermost film, or at an interface between the uppermost film and the lower layer (film or wafer). Then, the light is emitted as reflected light. That is, the reflected light includes light having two components having different phases. Further, as the film thickness of the surface increases, the phase difference increases. Therefore, when the film thickness is changed, the degree of interference between the light reflected at the film surface and the light reflected at the interface with the lower layer described above is changed. That is, the shape of the spectroscopic spectrum of the reflected light is changed. The change in the spectroscopic spectrum according to the film thickness may be theoretically calculated. Therefore, in the control device 100, information related to the shape of the spectroscopic spectrum according to the film thickness of the film formed on the surface is held in advance. Then, the spectroscopic spectrum of the reflected light obtained by irradiating light to the actual wafer W is compared with the information held in advance. As a result, it is possible to estimate the film thickness of the film of the surface of the wafer W. The information related to the relationship between the film thickness and the shape of the spectroscopic spectrum used for estimating the film thickness is held in the spectroscopic information holding unit 109 of the control device 100.

Specifically, the method for calculating the film thickness from the spectroscopic spectrum data is as illustrated in FIG. 9. First, after acquiring a result of the spectroscopic measurement, that is, the spectroscopic spectrum data (step S21), the spectroscopic spectrum data is compared with the information held in the spectroscopic information holding unit 109, that is, information related to the shape of the spectroscopic spectrum corresponding to the theoretical film thickness (step S22). Therefore, it is possible to estimate the film thickness of the region where the spectroscopic spectrum data is obtained for each spectroscopic spectrum data (step S23). As a result, it is possible to estimate the film thickness for each spectroscopic spectrum data, that is, at each position of the surface of the wafer W. As described above, since the spectroscopic spectrum data is obtained at a plurality of locations along the center line L in one wafer W, it is possible to obtain information related to the distribution of the film thickness on the surface of the wafer W by calculating the film thickness based on each spectroscopic spectrum data.

Since the image data of the wafer W imaged by the imaging unit 33 is an image of the entire surface of the wafer W, it is possible to estimate the film thickness of the entire surface of the wafer W from the image data. Meanwhile, in the estimation of the film thickness based on the spectroscopic spectrum data acquired by the spectroscopic measuring unit 40, the location where the spectroscopic spectrum data is acquired is limited to the center line L of the wafer W. Therefore, in the estimation of the film thickness of the film of the surface of the wafer W based on the spectroscopic spectrum data, it is possible to evaluate the overall distribution of the film thickness as compared with the estimation of the film thickness based on the image data. However, it is possible to measure the film thickness at a plurality of locations along the center line L by the spectroscopic measurement on one line described above. Therefore, when there is abnormality in the in-plane distribution of the film thickness of the film formed on the surface of the wafer W, it is considered to be able to detect some change such as variation in the film thickness estimated from a plurality of spectroscopic spectrum data.

As described above, the estimation of the film thickness based on the image data is limited to a case where the film formed on the wafer W is thin to some extent. Meanwhile, it is possible to estimate the film thickness based on the spectroscopic spectrum data not only when the film formed on the wafer W is thick to some extent, but also when the film thickness is small (e.g., tens of nm). In this manner, it is considered that the estimation of the film thickness based on the spectroscopic spectrum data is highly versatile since it is not easily limited to the thickness of the wafer W. However, a predetermined pattern is formed on the wafer W. As a result, spectroscopic spectrum data affected by the unevenness of the pattern may be obtained. As a result, the spectroscopic spectrum data acquired from the wafer W may not always accurately reflect the film thickness of the film formed on the wafer W. It is necessary to handle the spectroscopic spectrum data in consideration of this point. Further, it is required to consider that the film thickness estimated from the spectroscopic spectrum data may also not be accurate. However, this problem may be solved if the position at which the spectroscopic spectrum data is acquired may be specified more accurately. That is, when acquiring the spectroscopic spectrum related to the surface of the patterned wafer W, it is possible to avoid a decrease in accuracy due to a pattern if it is possible to control to acquire the spectroscopic spectrum data at a position different from the position where a step is formed.

When the estimation of the film thickness is performed based on the spectroscopic spectrum data, the image data may be used for, for example, evaluation of the film formation status. The evaluation of the film formation states relates to whether there is abnormality that may be detected from the image data such as whether there is a defect such as a spot on the film surface. As a result, the film formation status may be evaluated in more detail by acquiring both the image data and the spectroscopic spectrum data. For example, it is assumed that it is possible to detect from the image data that there is a defect in some regions on the center line L of the wafer W, which is the target from which the spectroscopic spectrum data is acquired. In this case, the accuracy of the estimated value may be increased by specifying the spectroscopic spectrum data of the location overlapping or adjacent to that region and not using the spectroscopic spectrum data for calculating the average value of the film thickness estimation. Further, the image corresponding to the defective region and the estimated value of the film thickness based on the spectroscopic spectrum data of the location may be automatically associated and store. Therefore, since it is possible to withdraw simply and reliably information in the depth direction in the plane region where the defect has occurred, for example, it is possible to improve the efficiency or high accuracy of the work of analyzing the state of the defect or the reason for the occurrence after the fact. In this manner, with the configuration in which the evaluation of the film formation status of the surface of the substrate is performed based on the image data, the spectroscopic spectrum data may be utilized widely depending on the film formation status obtained from the image data.

When the estimation of the film thickness is performed based on the image data, the acquiring the spectroscopic spectrum data (step S03) may be omitted. In this case, the spectroscopic spectrum data by the spectroscopic measuring unit 40 itself may not be obtained, and the estimation of the film thickness and the evaluation of the film formation status may be performed based on only the image data.

Returning to FIG. 6, after calculating the film thickness (step S04), the inspection executing unit 101 of the control device 100 executes step S05. In step S05, the wafer W is carried out from the inspecting unit U3. The wafer W carried out is sent to, for example, a processing module in a subsequent step.

Subsequently, the determining unit 105 of the control device 100 executes step S06 (determining step). In step S06, it is confirmed whether the film thickness of the wafer W has reached the acceptance criteria. The acceptance criteria are based on whether the film thickness of the entire wafer W is included in a predetermined film thickness setting range. That is, in step S06, it is evaluated whether the film formation is appropriately performed in the coating unit U1 and the heat treatment unit U2 in the previous step.

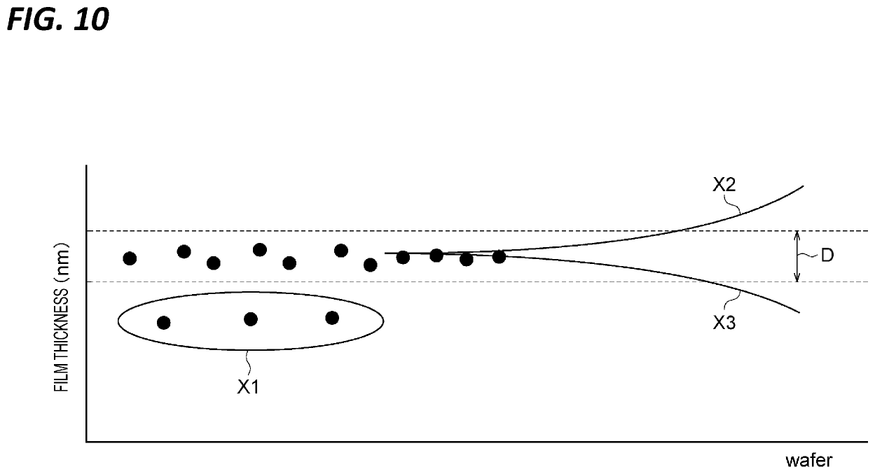

The criteria related to the determination on pass or not for the film thickness in step S06 will be described with reference to FIG. 10. A set value (setting range) of the film thickness is set for each film formed on the wafer W. In FIG. 10, a setting range D of the film thickness is illustrated, and the estimation results of the film thickness of a plurality of wafers W are illustrated as dots in time series, respectively. As described above, the film thickness at a plurality of locations on the surface of one wafer W is estimated based on either one of the image data and the spectroscopic spectrum data. It is assumed that the estimation result of the average value of the film thickness at a plurality of locations on one wafer W is illustrated in FIG. 10. Here, an example in which one wafer is sampled for estimation for each one lot (25 wafers) with respect to the wafer W on which the same substrate processing is performed is illustrated. However, the present disclosure is not limited thereto, and for example, one wafer may be sampled for every 10 wafers, or for every one hour lapse.

Here, when the estimation results of the film thickness at all the locations related to the plurality of wafers W processed along time series are included in the setting range D, it may be determined that the wafer W is passed. Meanwhile, as illustrated by X1 in FIG. 10, when the estimation results of the film thickness outside the setting range D are illustrated, it may be determined that the wafer W does not reach the acceptance criteria. Further, a configuration that considers the bias of the film thickness as the acceptance criteria may be used. For example, when the film thickness is estimated from the spectroscopic spectrum data, as illustrated by a solid line X2 or a solid line X3 in FIG. 10, a result in which the estimation results of a plurality of film thicknesses processed along time series gradually deviate from the setting range D may be obtained. In this case, even if the estimation result of the film thickness of the wafer W is included in the setting range D at this step, thereafter, it may be possible that the film thickness will deviate from the setting range D. As a result, after determining that the wafer W is failed, a detailed inspection (QC inspection to be described later) related to the device may be performed. In this manner, the criteria (acceptance criteria) for determining pass or not for the film thickness in step S06 may be appropriately changed depending on the changing status in time series.

When the determination on pass or not related to the film thickness is to be passed (YES in S06), the inspection executing unit 101 of the control device 100 executes step S07. In step S07, it is determined whether the inspection related to the subsequent wafer W is executed or not, and the inspection is ended (YES in S07), or the inspection related to the subsequent wafer W is started (NO in S07).

Meanwhile, when the determination on pass or not related to the film thickness is to be failed (NO in S06), the control device 100 determines that the detailed inspection is to be performed, and the inspection executing unit 106 executes step S08. Step S08 is the detailed inspection (QC inspection) related to the film thickness.

The detailed inspection is an inspection using a bare wafer (a wafer having a surface on which, for example, a patterning is not performed) called a QC wafer (inspection substrate). In the detailed inspection, the QC wafer is carried into the coating unit U1 and the heat treatment unit U2 and the film formation is performed under the same conditions as the normal wafer, and then, the film thickness is evaluated in more detail than the normal wafer in the inspecting unit U3. The detailed inspection is useful especially when estimating the film thickness of the normal wafer W using the spectroscopic spectrum data. When the film thickness is evaluated using the spectroscopic spectrum data in the inspection related to the normal wafer W, the evaluation of the distribution of the film thickness is not for the entire surface of the wafer W with respect to the normal wafer W. Therefore, when the wafer W is determined to be failed in the determination on pass or not (step S06), it is necessary to grasp what kind of film thickness is in the region where the film thickness is not estimated. The detailed inspection corresponds to this inspection.

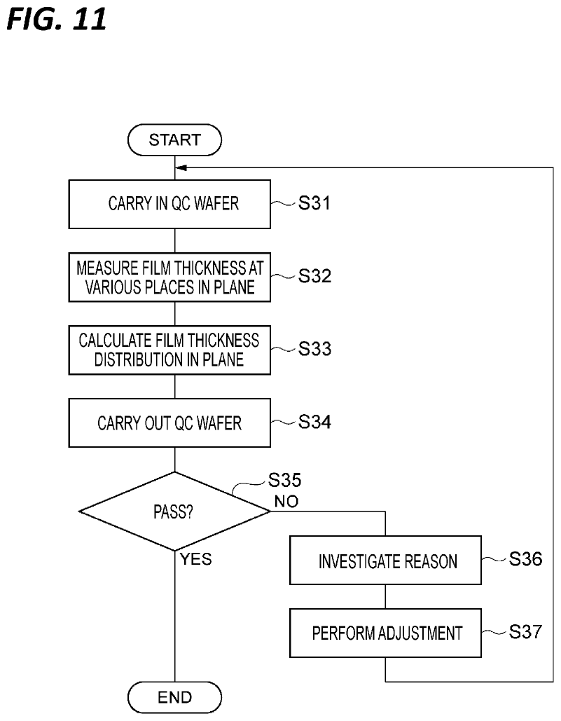

The procedure of the detailed inspection will be described with reference to FIG. 11. First, the detailed inspection executing unit 106 of the control device 100 executes step S31. In step S31, after finishing the film formation processing in the coating unit U1 and the heat treatment unit U2 on the QC wafer, the QC wafer is carried into the inspecting unit U3. That is, the film formation processing (film forming step) is performed on the QC wafer under the same conditions as the wafer W which is a target substrate, and then the QC wafer is carried into the inspecting unit U3. The QC wafer carried in is held by the holding unit 31.

Subsequently, the inspection executing unit 106 of the control device 100 executes step S32 (detailed measuring step). In step S32, the film thickness is measured at various places in the plane. When measuring the film thickness, the spectroscopic spectrum data is acquired at multiple points. The points where the film thickness is performed are distributed over the entire surface of the QC wafer. In the case of the normal wafer W, the spectroscopic spectrum data is acquired at the same time as the acquisition of the image data, and thus, a plurality of spectroscopic spectrum data is acquired along the center line L of the wafer W in accordance with the movement of the holding unit 31 in one direction. Meanwhile, in the measurement of the film thickness at the multiple points in the plane, the holding unit 31 is moved while changing the direction of the QC wafer held by the holding unit 31. Therefore, the inspecting unit U3 may be used to acquire the spectroscopic spectrum data at various measurement locations distributed and arranged two-dimensionally on the surface of the wafer.

When the spectroscopic spectrum data is acquired, the film thickness calculating unit 104 of the control device 100 executes step S33 (detailed measuring step). In step S33, based on each of the plurality of spectroscopic spectrum data related to the surface of the wafer W, the film thickness of the film of the surface of the wafer W is calculated, and the film thickness distribution in the plane is calculated. The procedure when the film thickness is calculated using the spectroscopic spectrum data may use the same method as for calculating the film thickness related to the normal wafer W, and is specifically illustrated in FIG. 9.

After calculating the film thickness distribution (step S33), the detailed inspection executing unit 106 of the control device 100 executes step S34. In step S34, the QC wafer is carried out from the inspecting unit U3. The wafer W carried out is sent to, for example, a processing module in a subsequent step.

Subsequently, the determining unit 105 of the control device 100 executes step S35. In step S35, it is confirmed whether the film thickness of the wafer W has reached the acceptance criteria. The acceptance criteria in here are based on whether the film thickness distribution measured on the surface of the QC wafer is included in a predetermined film thickness setting range. That is, in step S33, it is evaluated whether the film formation is appropriately performed on the entire surface of the wafer in the coating unit U1 and the heat treatment unit U2 in the previous step.

When the determination on pass or not related to the film thickness distribution is to be passed (YES in S35), the detailed inspection executing unit 106 of the control device 100 ends a series of processing. Meanwhile, when the determination on pass or not related to the film thickness distribution is to be failed (NO in S35), the detailed inspection executing unit 106 of the control device 100 notifies, for example, an operator that the film formation is not properly performed by, for example, sending an error message. Then, the reason why the film thickness is improper is investigated (step S36), and the part related to the reason is adjusted (step S37). Thereafter, the QC wafer is introduced again (step S31), and a series of detailed inspection is performed. The investigation of the reason (step S37) and the adjustment (step S38) may be performed independently by the control device 100. Further, these steps may be performed by configuring such that the control device 100 performs only the error notification, and manipulating the control device 100 by, for example, an operator of the control device 100 (substrate processing system 1).

The detailed inspection (QC inspection) is performed repeatedly until the determination on pass or not (step S35) related to the in-plane distribution of the film thickness of the surface of the wafer is to be passed. In other words, when the determination on pass or not (step S35) is to be passed, it may be said that the film formation related to the normal wafer W may be restarted. That is, as illustrated in FIG. 6, when the processing is not ended (NO in S07), the inspection in which the normal wafer W is carried in may be restarted.

[Method for Creating Model Used in Method for Inspecting Substrate]

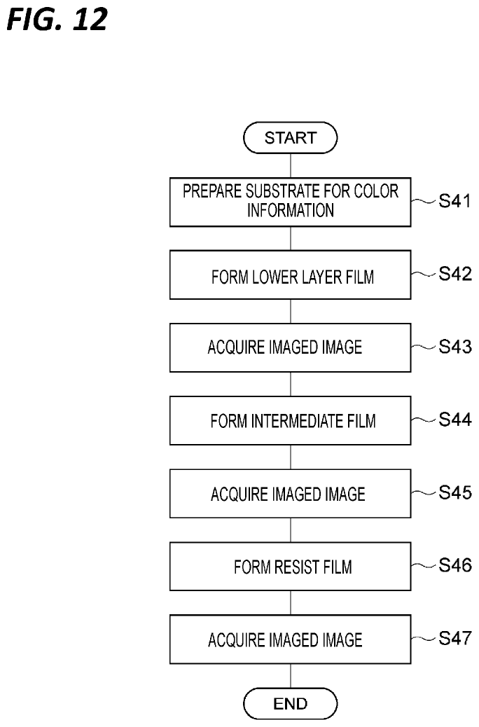

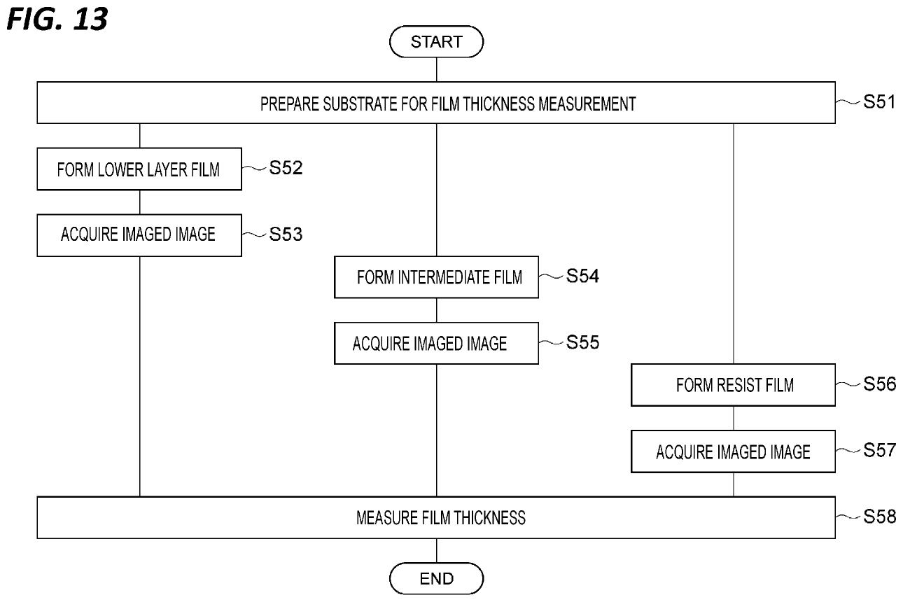

Subsequently, a method for creating a model (film thickness model) used in the method for inspecting a substrate by the control device 100 will be described with reference to FIGS. 12 and 13. As described above, the film thickness model is associated with the correspondence relationship between the film thickness and the color information of the image data. Therefore, with respect to the wafer W having a known film thickness, the correspondence relationship between the film thickness and the color information by specifying the color information from the image data obtained by imaging the wafer W. In order to accurately measure the film thickness when the film formation is performed on the wafer, it is required to measure the film thickness when the film formation is performed on the wafer (bare wafer) on which a patterning is not performed by, for example, cross-sectional measurement.

Therefore, the film thickness information and the color information used in the film thickness model are acquired. Here, a bare wafer (substrate for color information), on which a patterning is not performed, used for acquiring the color information, and a bare wafer (substrate for film thickness measurement), on which a patterning is not performed, used for measuring the film thickness are used.

Descriptions will be made on a method for acquiring the color information using the bare wafer, which is a substrate for color information, in the model creation by the control device 100 with reference to FIG. 12.

First, the model creating unit 107 of the control device 100 executes step S41. In step S41, the substrate for color information is prepared. The bare wafer is prepared as described above as the substrate for color information. Further, the bare wafer used as the substrate for color information is imaged in the inspecting unit U3 in this step, and thus, the image data related to the substrate before film formation is acquired. The image data obtained at this time is used for acquiring the color information of the surface of the wafer after forming the lower layer film.

Subsequently, the model creating unit 107 of the control device 100 executes step S42. In step S42, each unit of the processing module 11 is controlled to form the lower layer film with respect to the prepared substrate for color information. Here, the lower layer film is formed with a predetermined setting.

Subsequently, the model creating unit 107 of the control device 100 executes step S43. In step S43, the inspecting unit U3 in the processing module 11 is controlled to acquire the image data related to the surface of the substrate for color information, on which the lower layer film is formed. The image data obtained at this time is used for acquiring the color information of the surface of the wafer after forming the lower layer film.

Subsequently, the model creating unit 107 of the control device 100 executes step S44. In step S44, each unit of the processing module 12 is controlled to form the intermediate film on the lower layer film of the substrate for color information. Here, the intermediate film is formed with a predetermined setting.

Subsequently, the model creating unit 107 of the control device 100 executes step S45. In step S45, the inspecting unit U3 in the processing module 12 is controlled to acquire the image data related to the surface of the substrate for color information, on which the intermediate film is formed. The image data obtained at this time is used for acquiring the color information of the surface of the wafer after forming the intermediate film.

Subsequently, the model creating unit 107 of the control device 100 executes step S46. In step S46, each unit of the processing module 13 is controlled to form the resist film on the intermediate film of the substrate for color information. Here, the intermediate film is formed with a predetermined setting.

Subsequently, the model creating unit 107 of the control device 100 executes step S47. In step S47, the inspecting unit U3 in the processing module 13 is controlled to acquire the image data related to the surface of the substrate for color information, on which the resist film is formed. The image data obtained at this time is used for acquiring the color information of the surface of the wafer after forming the resist film.

In this manner, with respect to the substrate for color information, similar to the substrate processing process related to the actual wafer W, the lower layer film, the intermediate film, and the resist film are formed, and the image data is acquired every time the film is formed. Therefore, it is possible to acquire the image data of the surface of the substrate for color information produced under the same conditions as the film formation on the wafer W.

Subsequently, descriptions will be made on a method for acquiring the film thickness information using the substrate for film thickness measurement in the procedure of the model creation by the control device 100 with reference to FIG. 13. The substrate for film thickness measurement is used to accurately calculate the thickness of the film formed on the wafer when the film is formed under a predetermined condition. Therefore, when forming three types of films of the lower layer film, the intermediate film, and the resist film on the wafer, a bare wafer on which no other film is formed on the lower layer is used when forming each film. As a result, it is possible to accurately measure the film thickness without being affected by a slight change in the film thickness due to the formation of another film on the lower layer.

First, the model creating unit 107 of the control device 100 executes step S51. In step S51, the substrate for film thickness measurement is prepared. The substrate for film thickness measurement is a wafer on which, for example, a patterning is not performed. A plurality of substrates for film thickness measurement is prepared according to the number of films to be formed later.

Subsequently, the model creating unit 107 of the control device 100 executes step S52. In step S52, each unit of the processing module 11 is controlled to form the lower layer film with respect to the prepared substrate for film thickness measurement. Here, the lower layer film is formed with the same setting (a predetermined setting) as that of the substrate for color information.

Subsequently, the model creating unit 107 of the control device 100 executes step S53. In step S53, the inspecting unit U3 in the processing module 11 is controlled to acquire the image data related to the surface of the substrate for film thickness measurement, on which the lower layer film is formed. The image data of the bare wafer obtained at this time may be used for creating a model for color information of the surface of the wafer after forming the lower layer film.

Subsequently, the model creating unit 107 of the control device 100 executes step S54. In step S54, each unit of the processing module 12 is controlled to form the intermediate film with respect to the substrate for film thickness measurement. Here, the intermediate film is formed with the same setting (a predetermined setting) as that of the substrate for color information. However, unlike the substrate for color information, the film is formed on a bare wafer on which nothing is formed.

Subsequently, the model creating unit 107 of the control device 100 executes step S55. In step S55, the inspecting unit U3 in the processing module 12 is controlled to acquire the image data related to the surface of the substrate for film thickness measurement, on which the intermediate film is formed. The image data obtained at this time may be used for creating a model for color information of the surface of the wafer after forming the intermediate film.

Subsequently, the model creating unit 107 of the control device 100 executes step S56. In step S56, each unit of the processing module 12 is controlled to form the resist film with respect to the substrate for film thickness measurement. Here, the resist film is formed with the same setting (a predetermined setting) as that of the substrate for color information. However, unlike the substrate for color information, the film is formed on a bare wafer on which nothing is formed.

Subsequently, the model creating unit 107 of the control device 100 executes step S57. In step S57, the inspecting unit U3 in the processing module 12 is controlled to acquire the image data related to the surface of the substrate for film thickness measurement, on which the resist film is formed. The image data obtained at this time may be used for creating a model for color information of the surface of the wafer after forming the resist film.

In this manner, with respect to the substrate for film thickness measurement, the film formation of the lower layer film, the intermediate film, and the resist film, which is performed on the actual wafer W, is individually performed on the bare wafers different from each other. As a result, a plurality of substrates for film thickness measurement is prepared according to the number of film formation processes.

Then, after performing these processings, the model creating unit 107 of the control device 100 executes step S58. In step S58, the film thickness is measured for each of the substrate for film thickness measurement on which the lower layer film is formed, the substrate for film thickness measurement on which the intermediate film is formed, and the substrate for film thickness measurement on which the resist film is formed. The measurement of the film thickness may be performed using the spectroscopic measuring unit 40 described above. That is, as described above, it is possible to calculate the film thickness using the spectroscopic spectrum data by using the change in reflectance according to the film thickness of the film of the surface. That is, the reflected light from the wafer used for acquiring the spectroscopic spectrum data includes light having components having different phases according to the film thickness. By using this, it becomes possible to specify the film thickness from the change in the shape of the spectroscopic spectrum. As described above, when a desired film is formed on the surface of the bare wafer that is used as the substrate for film thickness measurement, since the lower surface of the film is flat, the shape of the spectroscopic spectrum reflects the film thickness of the film formed on the surface of the substrate for film thickness measurement. Therefore, it is possible to accurately calculate the film thickness from the spectroscopic spectrum data obtained by imaging the substrate for film thickness measurement. The calculation of the film thickness from the spectroscopic spectrum data is the same as the method described with reference to FIG. 9.

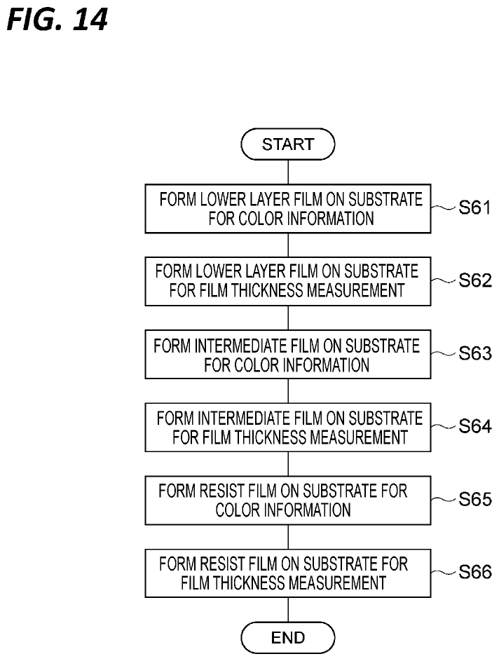

The image data in each step in the state where the film is formed on the substrate for color information, and the information for specifying the film thickness when the film is formed on the substrate for film thickness measurement under the same condition may be acquired by going through the processings illustrated in above FIGS. 12 and 13. As a method for making the film formation conditions of the substrate for color information and the substrate for film thickness measurement as described above, for example, each film formation may be performed in the order illustrated in FIG. 14.

Specifically, first, the lower layer film is formed on the substrate for color information (step S61), and at the same time or thereafter, the lower layer film is formed on the substrate for film thickness measurement (step S62). Further, the intermediate film is formed on the substrate for color information on which the lower layer film is formed (step S63), and at the same time or thereafter, the intermediate film is formed on the substrate for film thickness measurement (step S64). Further, the resist film is formed on the substrate for color information on which the intermediate film is formed (step S65), and at the same time or thereafter, the resist film is formed on the substrate for film thickness measurement (step S66). In this manner, it is possible to form the film on both the substrate for color information and the substrate for film thickness measurement under a closer condition by making the film formation timing for the substrate for color information and the film formation timing for the substrate for film thickness measurement as close as possible. It is desirable that the film formation timing for the substrate for color information and the film formation timing for the substrate for film thickness measurement are close to each other. For example, after coating the processing liquid to the substrate for color information by the coating unit U1, the processing liquid is coated to the substrate for film thickness measurement by the coating unit U1. Then, after performing the heat treatment on the substrate for color information by the heat treatment unit U2, the heat treatment is performed on the substrate for film thickness measurement by the coating unit U2. In this manner, the film formation timings may become close by alternately performing the processing in each unit between the substrate for color information and the substrate for film thickness measurement.

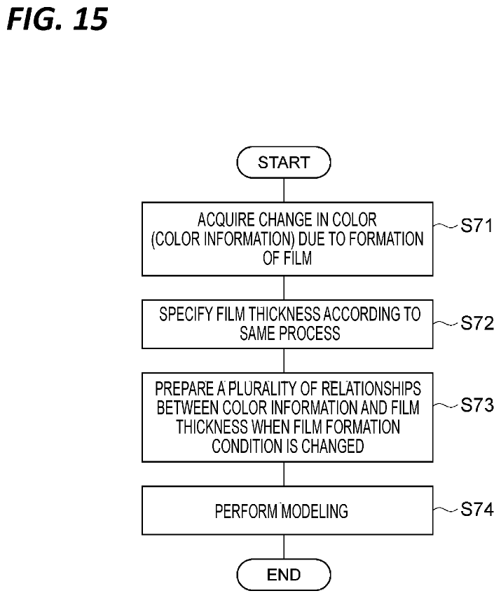

The film thickness model may be created by combining the data obtained from the above procedure. A procedure for creating the film thickness model by the model creating unit 107 of the control device 100 will be further described with reference to FIG. 15.

First, it is possible to acquire the information related to the change in color due to the formation of the film in each step from the image data obtained by imaging the substrate for color information (step S71: imaging step). For example, when creating a model related to the lower layer film, the image data obtained by imaging in the preparing step of the substrate for color information (step S41) and the image data obtained by imaging after forming the lower layer film (step S43) are compared with each other. By this comparison, it is possible to specify how much the color of the surface has changed when forming the lower layer film. Meanwhile, it is possible to specify the film thickness of the lower layer film (step S72: film thickness measuring step) by measuring the film thickness of the substrate for film thickness measurement (step S58) on which the lower layer film is formed under the same film formation condition. Therefore, it may be seen that, when the lower layer film having a predetermined film thickness (e.g., 100 nm) is formed on the substrate for color information, the change in color of this extent may be observed as color information. A plurality of combinations of the film thickness and the color information is prepared with different film thicknesses (step S73: model creating step). That is, a plurality of types of combination of the film thickness and the color information in a state where the film thickness is changed (e.g., 90 nm, 95 nm, 100 nm, and 110 nm) by changing the film formation condition is prepared. In this manner, by preparing the plurality of combinations, it is possible to specify, for example, a relational expression that specifies how the color information has changed in response to the change in film thickness. This corresponds to the modeling the change in color with respect to the film thickness, and thus, a film thickness model may be obtained (step S74: model creating step). Here, the example related to the lower layer film has been described, but a film thickness model may be created with respect to the intermediate film and the resist film by going through the same procedure.

The case where the substrate for color information is the bare wafer is described above, but the substrate for color information may use, for example, a patterned wafer on which a patterning corresponding to the target wafer W is performed. In this case, it is conceivable that the color information obtained by imaging the substrate for color information become closer to the actual wafer W.

### Application Example 1

A periphery exposing unit may be added to the inspecting unit U3 described in the embodiment to perform periphery exposure on the wafer W. In the following, an inspecting unit U4 that may be included in the processing module 12 will be described as an example.

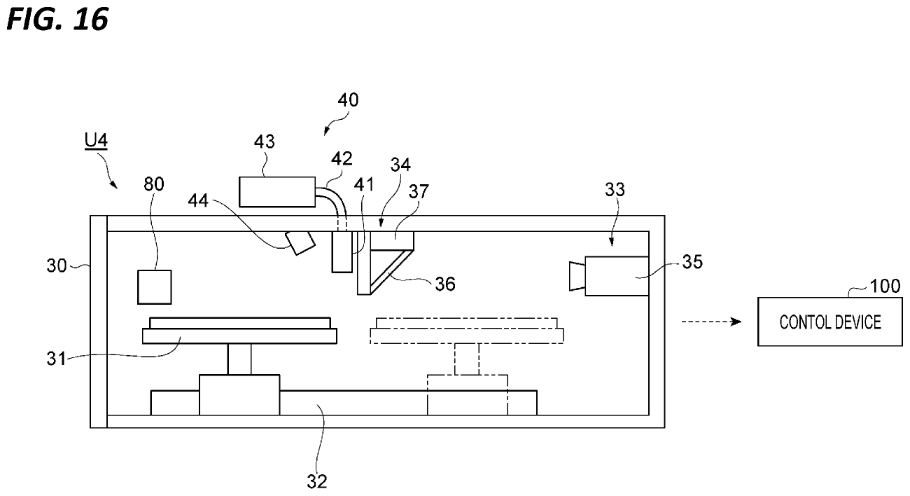

As illustrated in FIG. 16, the inspecting unit U4 includes the housing 30, the holding unit 31, the linear driver 32, the imaging unit 33, the light projecting/reflecting unit 34, the spectroscopic measuring unit 40, and a periphery exposing unit 80.

Among the respective parts of the inspecting unit U4, the housing 30, the holding unit 31, the linear driver 32, the imaging unit 33, the light projecting/reflecting unit 34, and the spectroscopic measuring unit 40 are configured in the same manner as the inspecting unit U3 described above. For this reason, the detailed descriptions thereof will be omitted. Among the respective parts of the inspecting unit U4, the constituent that does not included in the inspecting unit U3 may include the periphery exposing unit 80.

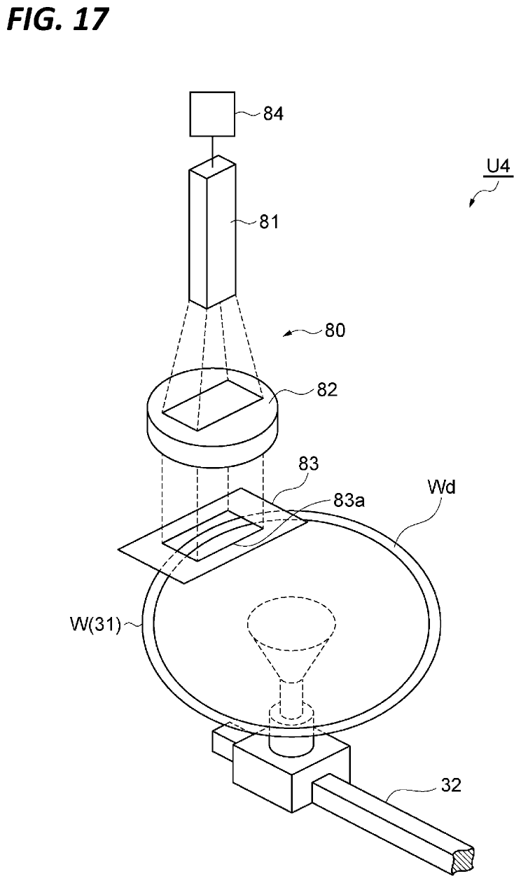

The periphery exposing unit 80 is configured to irradiate a peripheral edge region Wd (see FIG. 17) of the wafer W on which the resist film is formed with infrared rays, and perform an exposing processing on the portion of the resist film positioned in the peripheral edge region Wd. The periphery exposing unit 80 is positioned above the holding unit 31. As illustrated in FIG. 17, the periphery exposing unit 80 includes a light source 81, an optical system 82, a mask 83, and an actuator 84. The light source 81 irradiates energy rays (e.g., ultraviolet rays) containing wavelength components capable of exposing the resist film on the wafer W to the lower side (holding unit 31 side). For example, an ultra-high pressure UV lamp, a high pressure UV lamp, a low pressure UV lamp, and an excimer lamp may be used as the light source 81.

The optical system 82 is positioned below the light source 81. The optical system 82 is constituted by at least one lens. The optical system 82 converts the light from the light source 81 into substantially parallel light and irradiates the mask 83. The mask 83 is positioned below the optical system 82. The mask 83 includes an opening 83a for adjusting the exposure area. The parallel light from the optical system 82 passes through the opening 83a, and is irradiated to the peripheral edge region of a surface Wa of the wafer W held by the holding unit 31.

The actuator 84 is connected to the light source 81. The actuator 84 is, for example, an elevating cylinder, and moves the light source 81 up and down in the vertical direction. That is, the light source 81 is movable between a first height position (lowered position) that is close to the wafer W held by the holding unit 31, and a second height position (raised position) away from the wafer W held by the holding unit 31, by the actuator 84.

The inspecting unit U4 may also be controlled by the control device 100. As described above, among the respective parts included in the inspecting unit U4, each part other than the periphery exposing unit 80 has the same function as the inspecting unit U3. Further, with respect to the periphery exposing unit 80, the wafer W is held by the holding unit 31, and the wafer W is rotated at a predetermined rotation speed (e.g., approximately 30 rpm) at a predetermined position. In this state, the control device 100 controls the periphery exposing unit 80 so as to perform the periphery exposure by irradiating a resist film R positioned in the peripheral edge region Wd of the surface Wa of the wafer W with a predetermined energy ray (ultraviolet ray) from the light source 81.

The control device 100 may perform a wafer W surface inspection in the same manner as the inspecting unit U3 on the wafer W before and after the periphery exposure by driving the holding unit 31, the linear driver 32, the imaging unit 33, the light projecting/reflecting unit 34, and the spectroscopic measuring unit 40.

### Application Example 2

The spectroscopic measuring unit 40 in the inspecting unit U4 described in the Application Example 1 may be omitted, and only the inspection using the image data of the surface of the wafer W acquired by operating the imaging unit 33 and the light projecting/reflecting unit 34 may be performed. In the following, an inspecting unit U5 that may be included in the processing module 12 will be described as an example.

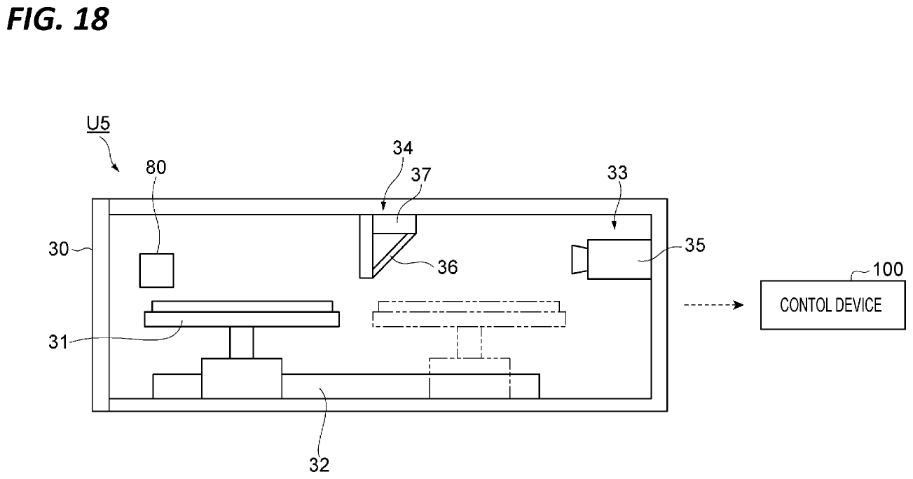

As illustrated in FIG. 18, the inspecting unit U5 includes the housing 30, the holding unit 31, the linear driver 32, the imaging unit 33, the light projecting/reflecting unit 34, and the periphery exposing unit 80. The respective parts of the inspecting unit U5 are configured in the same manner as the inspecting unit U4 described above. Therefore, the detailed descriptions thereof will be omitted. The control device 100 may perform a wafer W surface inspection in the same manner as the inspecting unit U4 on the wafer W before and after the periphery exposure by driving the holding unit 31, the linear driver 32, the imaging unit 33, and the light projecting/reflecting unit 34. That is, the imaging operation in step S02 in FIG. 6 and the film thickness calculation in FIG. 8 may be performed.

### Application Example 3

The imaging unit 33 and the light projecting/reflecting unit 34 in the inspecting unit U4 described in the embodiment may be omitted, and only the inspection using the spectroscopic data of the surface of the wafer W acquired by operating the spectroscopic measuring unit 40 may be performed. In the following, an inspecting unit U6 that may be included in the processing module 12 will be described as an example.

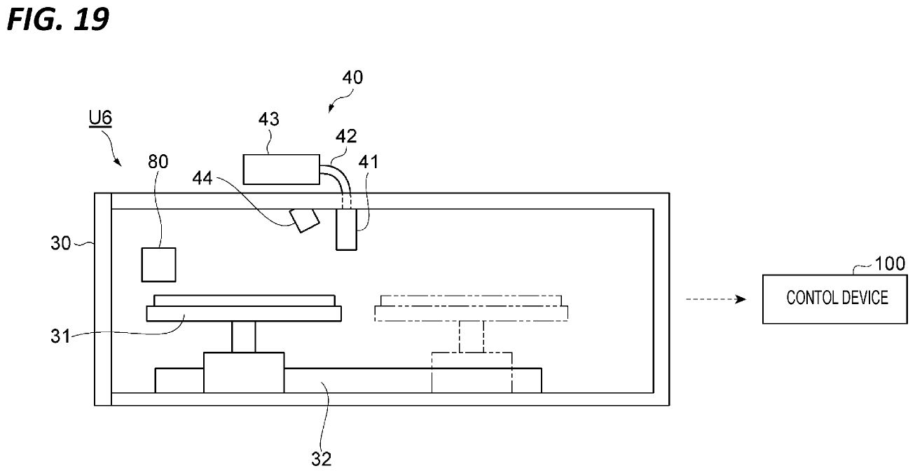

As illustrated in FIG. 19, the inspecting unit U6 includes the housing 30, the holding unit 31, the linear driver 32, the spectroscopic measuring unit 40, and the periphery exposing unit 80. The respective parts of the inspecting unit U5 are configured in the same manner as the inspecting unit U4 described above. Therefore, the detailed descriptions thereof will be omitted. The control device 100 may perform a wafer W surface inspection in the same manner as the inspecting unit U4 on the wafer W before and after the periphery exposure by driving the holding unit 31, the linear driver 32, and the spectroscopic measuring unit 40. That is, the operations other than the imaging operation in step S02 in FIG. 6 may be performed.

### Application Example 4

In Application Examples 1 to 3, it has been described that the wafer W surface inspection in the same manner as the inspecting unit U3 may be performed on the wafer W before and after the periphery exposure. However, the present disclosure is not limited to the above configuration, but the inspection of the surface of the wafer W may be independently performed without being associated with the periphery exposing processing.

For example, the inspecting unit U4 in Application Example 1 and the inspecting unit U6 in Application Example 3 may function as the periphery exposing unit using the periphery exposing unit 80 with respect to the product wafer W, and function as the inspecting unit using the spectroscopic measuring unit 40 with respect to the QC wafer. The inspection timing of the QC wafer is not limited to the case where the failed wafer occurs as in step S08 in FIG. 6, but may be an arbitrary timing.

Further, for example, in Application Example 2, after the periphery exposure, the wafer W may be transferred once from the inspecting unit U5 to the coating unit U1 to perform the developing processing, and the inspecting unit U5 may inspect the wafer W again after the development.

[Effect]

As described above, in the substrate processing apparatus according to the embodiment, the inspecting unit U3 includes the holding unit 31 that holds the substrate having a film formed on the surface; the imaging unit 33 that acquires image data by imaging the surface of the substrate held by the holding unit 31; and the spectroscopic measuring unit 40 that acquires spectroscopic data by dispersing light from the surface of the substrate held by the holding unit 31.

As described above, with a configuration in which, in a state of being held by the holding unit 31, the image data obtained by imaging the surface of the substrate may be acquired, and the spectroscopic data related to light from the surface may be acquired, it is possible to accurately evaluate the film formed on the substrate.

In the related art, the state of the film is evaluated from the image data obtained by imaging the surface of the substrate. However, the state of the film may not properly be evaluated using the image data alone. In particular, when a film having a large film thickness is formed on the surface of the substrate, the film formation status may not accurately be evaluated using the image data alone. Meanwhile, it is conceivable to provide, for example, a new inspecting unit for evaluating the state of the film, but processings related to the evaluation of the film may be increased and the amount of the work related to the substrate processing may also be increased. Meanwhile, as described above, with the configuration in which the image data acquisition and the spectroscopic data acquisition are performed in the inspecting unit U3, the film on the substrate may accurately be evaluated without providing, for example, a new unit. In particular, since the evaluation may be performed using spectroscopic data, it is possible to accurately evaluate a substrate on which a film having a film thickness that makes the appropriate evaluation difficult using the image data alone is formed.

Further, the imaging unit 33 may acquire an image related to the entire surface of the substrate, and the spectroscopic measuring unit 40 may acquire spectroscopic data by dispersing light from a plurality of different regions included in the surface of the substrate, respectively.

With such a configuration, it is possible to acquire information related to the entire surface of the substrate from the image data acquired by the imaging unit, and thus, the overall evaluation on the surface of the substrate may be performed. Meanwhile, since the spectroscopic measuring unit may acquire the spectroscopic data related to a plurality of different regions included in the surface of the substrate, it is possible to acquire information related to spectroscopic characteristics at a plurality of positions in the substrate, and thus, the evaluation using, for example, variations in the spectroscopic characteristics may be performed. Therefore, it is possible to evaluate the film of the surface of the substrate in a more multifaceted manner.

Further, the substrate processing apparatus further includes the control device 100 serving as a controller configured to control the holding unit 31, the imaging unit 33, and the spectroscopic measuring unit 40. The controller causes the imaging unit 33 to image the surface of the substrate while moving the holding unit 31 in one direction, and in parallel, causes the spectroscopic measuring unit 40 to acquire spectroscopic data by dispersing light from a plurality of different regions included in the surface of the substrate.

With such a configuration, it is possible to simultaneously acquire the image data by the imaging unit 33 and to acquire the spectroscopic data by the spectroscopic measuring unit 40 while moving the holding unit 31 in one direction. Therefore, even though both the image data and the spectroscopic data are acquired, it is possible to prevent the required time from becoming long, and the image data and the spectroscopic data may efficiently be acquired.

Further, the above-described control device 100 may evaluate a film formation status of the surface of the substrate based on the image data imaged by the imaging unit 33.

As described above, with the configuration in which the film formation status of the surface of the substrate is evaluated based on the image data, for example, the handling of the spectroscopic data may be changed based on the evaluation result of the film formation status based on the image data. As a result, the image data and the spectroscopic data may be handled more appropriately in the inspection of the substrate.

Further, as in the inspecting unit U4 described in the embodiment, in addition to the function as the inspecting unit U3, the periphery exposing unit 80 that exposes the peripheral edge region may be further provided. Even in this case, with a state of being held by the holding unit 31, the image data obtained by imaging the surface of the substrate may be acquired, and the spectroscopic data related to light from the surface may be acquired, and thus, it is possible to accurately evaluate the film formed on the substrate. Since it is not necessary to separately provide a periphery exposing unit, it is possible to suppress an increase in the size of the apparatus.

In the above-described inspecting unit U4, the control device 100 may cause the spectroscopic measuring unit 40 to acquire spectroscopic data by dispersing light from a plurality of locations on each of the substrate before and after exposure by the periphery exposing unit. Therefore, the effort and the time for transferring the substrate may be saved as compared with the case where the periphery exposing unit is separately provided, and it is possible to improve the throughput as a whole.

Further, the method for inspecting a substrate described in the above-described embodiment is a method for inspecting a substrate after film formation includes: acquiring image data by imaging a surface of the substrate held by a holding unit; acquiring spectroscopic data by dispersing light from some regions included in the surface of the substrate held by the holding unit by a spectroscopic measuring unit; determining whether the film meets acceptance criteria based on the image data and the spectroscopic data; when the film does not meet the acceptance criteria in the determining, performing a same film formation processing on an inspection substrate as for the substrate; and acquiring spectroscopic data by dispersing light from measurement positions two-dimensionally dispersed on the surface of the inspection substrate after film formation held by the holding unit by the spectroscopic measuring unit, respectively.

In this manner, it is determined whether the film formed on the substrate meets the acceptance criteria based on the image data and the spectroscopic data. Then, as a result, when the film does not meet the acceptance criteria, a film formation processing is performed on the inspection substrate, and with respect to the inspection substrate after the film formation, spectroscopic data from the measurement positions two-dimensionally dispersed using the spectroscopic measuring unit is acquired and a detailed measurement is performed. With this configuration, when a film formed on a normal substrate does not meet the acceptance criteria, a detailed measurement related to the inspection substrate after the film formation may be performed using the same spectroscopic measuring unit. Further, with respect to the normal substrate, not only the film may appropriately be evaluated based on image data and spectroscopic data, but also the detailed inspection for the case where the film does not meet acceptance criteria may be performed using the same spectroscopic measuring unit, and thus, the film may be evaluated in more detail.

In the acquiring image data, the surface of the substrate is imaged by the imaging unit while moving the holding unit in one direction. At this time, in parallel with this, as the acquiring spectroscopic data, the spectroscopic data may be acquired by the spectroscopic measuring unit by dispersing light from a plurality of different regions included in the surface of the substrate, respectively.

With such a configuration, it is possible to simultaneously acquire the image data by the imaging unit 33 and to acquire the spectroscopic data by the spectroscopic measuring unit 40 while moving the holding unit 31 in one direction. Therefore, even though both the image data and the spectroscopic data are acquired, it is possible to prevent the required time from becoming long, and the image data and the spectroscopic data may efficiently be acquired.

Further, in the coating/developing apparatus 2 as the substrate inspecting system according to the embodiment, the imaging unit 33 that images the surface of the substrate for color information that is provided in the substrate processing apparatus, on which the same patterning as the target substrate is performed, and having a film formed on the surface, and acquires the image data is provided. Further, in the coating/developing apparatus 2, the film thickness measuring unit (spectroscopic measuring unit 40) that measures the film thickness of the substrate for film thickness measurement that is provided in the substrate processing apparatus, and having a film formed on the surface under the same condition as the substrate for color information is provided. Further, the model creating unit 107 that creates the film thickness model related to the correspondence relationship between the information related to the change in color of the surface of the substrate for color information due to the formation of the film obtained based on the image data and the film thickness of the substrate for film thickness measurement measured by the film thickness calculating unit 104 is provided.

Further, the method for inspecting a substrate according to the embodiment is a method for inspecting the substrate in the substrate inspecting system including the substrate processing apparatus for performing the film formation on the target substrate. Specifically, in the substrate processing apparatus, an imaging step in which image data is acquired by imaging the surface of the substrate for color information on which the same patterning as the target substrate is performed and having a film formed on the surface is provided. Further, in the substrate processing apparatus, a film thickness measuring step in which the film thickness of the substrate for film thickness measurement having a film formed on the surface under the same condition as the substrate for color information is measured is provided. Further, a model creating step in which the film thickness model related to the correspondence relationship between the information related to the change in color of the surface of the substrate for color information due to the formation of the film obtained based on the image data and the film thickness of the substrate for film thickness measurement measured in the film thickness measuring step is created is provided.

According to the substrate inspecting system and the method for inspecting a substrate, the information related to the change in color of the surface is acquired based on the image data of the surface of the substrate for color information, and the film thickness of the substrate for film thickness measurement having a film formed under the same condition is measured by the spectroscopic measuring unit 40. Then, by combining these information, the film thickness model related to the correspondence relationship between the information related to the change in color and the film thickness is created. Therefore, the model for calculating the film thickness of the film related to the target substrate may be created more simply.

In the related art, a method in which the relationship between the information obtained from the image data and the film thickness is preserved in advance, and the film thickness is estimated from the image data of the target substrate based on the relationship has been studied. However, in the related art, in order to accurately measure the film thickness of the film formed on the substrate, it is necessary to analyze the substrate with, for example, a film thickness measuring device provided separately from the substrate processing apparatus. As a result, it is considered that the work for creating the model for calculating the film thickness of the film related to the target substrate is complicated and the required time is also increased.

Meanwhile, in the substrate inspecting system and the method for inspecting a substrate described above, with respect to the film formed on the substrate for film thickness measurement, it is possible to specify the film thickness by the film thickness calculating unit 104 based on the inspection result (spectroscopic data by the spectroscopic measuring unit 40) in the inspecting unit U3. Specifically, it is possible to calculate the film thickness from the spectroscopic data using the spectroscopic measuring unit 40. Meanwhile, the information related to the change in color when forming a film may be acquired from the result of imaging by the imaging unit 33 in the inspecting unit U3 using the substrate for color information on which a patterning is performed in the same manner as the target substrate. Therefore, it is possible to create the model by combining the film thickness and the information by the model creating unit 107 of the control device 100. That is, since the model used to calculate the film thickness of the target substrate may be created using the inspection result in the inspecting unit U3 in the substrate processing apparatus, it is possible to create the model more easily as compared to the related art.

The imaging unit 33 may acquire the image data related to the target substrate by imaging the target substrate having a film formed on the surface, and further include the film thickness calculating unit 104 that estimates the film thickness of the target substrate based on the information related to the change in color of the surface of the target substrate due to the formation of the film obtained from the image data related to the target substrate, and the film thickness model.

Further, a film thickness calculating step in which the image data related to the target substrate is acquired by imaging the target substrate having a film formed on the surface, and the film thickness of the target substrate is estimated based on the information related to the change in color of the surface of the target substrate due to the formation of the film obtained from the image data related to the target substrate, and the film thickness model may be further provided.

With the above-described configuration, in the film thickness calculating unit 104, the film thickness of the target substrate is estimated based on the information related to the change in color of the surface of the target substrate due to the formation of the film obtained from the image data related to the target substrate and the film thickness model. Therefore, it is possible to properly perform with respect to the film thickness of the target substrate using the model obtained above.

Further, the substrate inspecting system further includes the coating unit U1 and the heat treatment unit U2 as a film forming unit that performs a plurality of processings for forming a film on each surface of the substrate for color information and the substrate for film thickness measurement. The film forming unit may alternately perform a processing related to the formation of the film on the substrate for color information and a processing related to the formation of the film on the substrate for film thickness measurement.

Further, in the film forming step in which a plurality of processings for forming a film on each surface of the substrate for color information and the substrate for film thickness measurement, the processing related to the formation of the film on the substrate for color information and the processing related to the formation of the film on the substrate for film thickness measurement may be alternately performed.

As described above, in the film forming unit that performs the film formation on the substrate for color information and the substrate for film thickness measurement, the film formation on both the substrate for color information and the substrate for film thickness measurement may be performed under a closer condition by alternately performing the processings on the substrates. Therefore, since the information related to the change in color obtained from the substrate for color information and the film thickness obtained from the substrate for film thickness measurement may be corresponded with each other more accurately, it is possible to create a model with higher accuracy.

The substrate for film thickness measurement may be a substrate having a flat surface.

As described above, since the measurement of the film thickness by the film thickness measuring unit may be performed more accurately by using the substrate having a flat surface as the substrate for film thickness measurement, and forming a film on the substrate for film thickness measurement and measuring the film thickness, it is possible to create a model with higher accuracy.

The imaging unit 33 and the spectroscopic measuring unit 40 as the film thickness measuring unit may be provided in the same unit.

Further, the imaging step and the film thickness measuring step may be performed in parallel.

In the embodiment, when the imaging unit 33 and the spectroscopic measuring unit 40 are provided in the same unit as in the inspecting unit U3, it is possible to implement an apparatus configuration for creating a simple model while preventing the increase in the size of the apparatus. Further, the processing time is shortened by performing the imaging step and the film thickness measuring step in parallel.

In the embodiment, the case where the imaging unit 33 and the spectroscopic measuring unit 40 are provided in the inspecting unit U3 has been described, but the film thickness measuring unit for creating the model may be provided in a unit different from the unit including the imaging unit 33. As described above, when the film thickness of the film formed on the substrate for film thickness measurement may be measured using the spectroscopic measuring unit 40 in the inspecting unit U3, the film thickness model may be created using this result. However, the method for measuring the film thickness is not limited to the acquisition of the spectroscopic spectrum data described above. Specifically, the unit for measuring the film thickness may be provided separately from the inspecting unit U3, and when creating the model, the measurement related to the film thickness of the film of the substrate for film thickness measurement may be performed using the unit for measuring the film thickness. In this case, when calculating the film thickness of the target substrate, the film thickness may be estimated and evaluated based on the image data acquired by the inspecting unit U3.

### Other Embodiment

Although various embodiments have been described above, the present disclosure is not limited to the embodiments described above, and various omissions, substitutions, and changes may be made. Further, it is possible to combine the elements in different embodiments to form other embodiments.

For example, in the above embodiment, the case where the inspecting unit U3 is provided in each of the processing modules 11, 12, and 13 has been described. However, the inspecting unit U3 may not be provided in each module, but may be provided independently of each module.

Further, the film formed by the above processing modules 11, 12, and 13 is an example, and is appropriately changed. For example, a film may be formed on the resist film. That is, the method for inspecting a film described in the embodiment is not limited to the type and the number of films, and may be applied to various films formed on the substrate.

Further, in the embodiment, the case where the spectroscopic measuring unit 40 is provided one location along the center line L of the wafer W has been described, but the spectroscopic measuring unit 40 may be provided along a line different from the center line L. However, when the spectroscopic measuring unit 40 is provided at a position corresponding to the center line L of the wafer W when the wafer W is moved in accordance with the movement of the holding unit 31, the spectroscopic spectrum data may be acquired at a plurality of regions along the center line L of the wafer W. Therefore, it is possible to obtain spectroscopic spectrum data in a wider range even though the spectroscopic measurement is performed along one line. Further, a plurality of spectroscopic measuring unit 40 may be provided. The case where the spectroscopic spectrum image is acquired by the spectroscopic measuring unit 40 has been described, the spectroscopic data acquired by the spectroscopic measuring unit 40 may not be spectrum data.

From the above description, it will be understood that the various embodiments of the present disclosure are described herein for a purpose of explanation, and that various modifications can be made without departing from the scope and gist of the present disclosure. Therefore, the various embodiments disclosed herein are not intended to be limiting, and the true scope and gist are indicated by the accompanying claims.

### DESCRIPTION OF SYMBOLS

1: substrate processing system
2: coating/developing apparatus (substrate inspecting system)
3: exposing apparatus
4: carrier block
5: processing block
6: interface block
11 to 14: processing module
30: housing
31: holding unit
32: linear driver
33: imaging unit
34: reflecting unit
35: camera
36: half mirror
37: light source
40: spectroscopic measuring unit
41: incident unit
42: waveguide
43: spectroscope
44: light source
80: periphery exposing unit
100: control device
101: inspection executing unit
102: image information holding unit
103: spectroscopic measurement result holding unit
104: film thickness calculating unit
105: determining unit
106: detailed inspection executing unit
107: model creating unit
108: model holding unit
109: spectroscopic information holding unit

1. A substrate processing apparatus comprising:
a substrate holding unit configured to hold a substrate having a film formed on a surface thereof;
a camera configured to acquire image data by imaging the surface of the substrate held by the substrate holding unit;
a spectrometer configured to acquire spectroscopic data by dispersing light from the surface of the substrate held by the substrate holding unit; and
a controller configured to control the substrate holding unit, the camera, and the spectrometer.

2. The substrate processing apparatus according to claim 1, wherein the camera acquires an image related to an entire surface of the substrate, and
the spectrometer acquires the spectroscopic data by dispersing light from a plurality of different regions included in the surface of the substrate.

3. The substrate processing apparatus according to claim 1, wherein the controller causes the camera to image the surface of the substrate while moving the substrate holding unit in one direction, and in parallel, causes the spectrometer to acquire the spectroscopic data by dispersing light from a plurality of different regions included in the surface of the substrate.

4. The substrate processing apparatus according to claim 3, wherein the controller evaluates a film formation status of the surface of the substrate based on the image data imaged by the camera.

5. The substrate processing apparatus according to claim 1, further comprising:
a periphery exposure configured to expose a peripheral edge region of the substrate held by the substrate holding unit,
wherein the controller controls the periphery exposure.

6. The substrate processing apparatus according to claim 5, wherein the controller causes the spectrometer to acquire the spectroscopic data by dispersing light from a plurality of locations on each of the substrate before and after exposure by the periphery exposure.

7. A substrate inspecting method for inspecting a substrate after film formation, the method comprising:
acquiring image data by imaging a surface of the substrate held by a substrate holding unit;
acquiring spectroscopic data by dispersing light from a portion of region included in the surface of the substrate held by the substrate holding unit thereby measuring spectroscopic of the light dispersed by a spectrometer;
determining whether the film meets an acceptance criteria based on the image data and the spectroscopic data;
when the film does not meet the acceptance criteria in the determining, performing a same film formation processing on an inspection substrate as in the substrate; and
acquiring spectroscopic data by dispersing each light from measurement positions that are two-dimensionally dispersed on the surface of the inspection substrate which is held by the substrate holder and completed with the same film formation processing.

8. The substrate inspecting method according to claim 7, wherein, in the acquiring image data, a camera images the surface of the substrate while moving the substrate holding unit in one direction, and in parallel, in the acquiring spectroscopic data, the spectrometer acquires the spectroscopic data by dispersing light from a plurality of different regions included in the surface of the substrate.

9. A non-transitory computer-readable storage medium having stored therein a program that causes an apparatus to execute the substrate inspecting method according to claim 7.
